(19) United States
(12) Patent Application Publication
(10) Pub. No.: US 2022/0393659 A1
(43) Pub. Date: Dec. 8, 2022

(54) ACOUSTIC WAVE DEVICE AND MANUFACTURING METHOD THEREOF

(71) Applicant: Unikorn Semiconductor Corporation, Hsinchu (TW)

(72) Inventors: TA-CHENG HSU, Hsinchu (TW); WEI-SHOU CHEN, Hsinchu (TW); CHUNG-JEN CHUNG, Hsinchu (TW); CHENG-TSE CHOU, Hsinchu (TW); TIEN-YU WANG, Hsinchu (TW); CHUN-YI LIN, Hsinchu (TW); YU-JIUN SHEN, Hsinchu (TW); WEI-CHING GUO, Hsinchu (TW)

(21) Appl. No.: 17/830,717

(22) Filed: Jun. 2, 2022

(30) Foreign Application Priority Data
Jun. 4, 2021 (TW) 110120341
May 24, 2022 (TW) 111119193

(51) Int. Cl. H03H 3/02; H03H 9/02; H03H 9/17

(52) U.S. Cl. CPC H03H 3/02; H03H 9/02031; H03H 9/173; H03H 9/175; H03H 9/176; H03H 2009/02212

(57) ABSTRACT

An acoustic wave device includes: a substrate; a first electrode on the substrate; a piezoelectric layer on the first electrode; and a second electrode on the piezoelectric layer. A bonding interface is located between the substrate and the first electrode. The full width at half maximum (FWHM) in the X-ray diffraction pattern of the crystal plane <002> of the piezoelectric layer is between 10 arc-sec and 3600 arc-sec.

### CROSS REFERENCE TO RELATED APPLICATIONS

This application claims priority to the benefit of Taiwan Patent Application No. 110120341, filed on Jun. 4, 2021 and Taiwan Patent Application No. 111119193 filed on May 24, 2022, and the entire contents of which are hereby incorporated by reference herein in their entireties.

### BACKGROUND

### Technical Field

The application relates to an acoustic wave device and a method for manufacturing the same, and in particular, to an acoustic wave device having an acoustic wave reflective layer or a cavity and a method for manufacturing the same.

### Description of the Related Art

In order for radio frequency communication devices (such as smartphones) to operate properly at a variety of radio frequencies and communication bands, an acoustic wave filter is required for filtering neighboring signals outside the frequency range of the filter. To meet the requirements of increasingly complex communication devices, it is necessary to use filters with different types and compositions of acoustic wave devices for different communication channels and communication devices, thereby providing the ability to tune in different bandwidths.

As communication devices are developed to be lighter, thinner, shorter, and more fashionable, and the frequency resources are getting more and more crowded, filters with high-performance acoustic devices (such as high Q factor and/or high electromechanical coupling efficiency) has drawn much attention. Although existing acoustic wave devices and the methods of forming them have generally been adequate for filters and various communication devices, they have not been entirely satisfactory in all respects.

### BRIEF SUMMARY OF THE DISCLOSURE

In accordance with some embodiments, a method for manufacturing an acoustic wave device is provided. The method includes the following steps: providing a growth substrate; forming a decomposition layer on the growth substrate, wherein the decomposition layer comprises a III-V compound semiconductor material; epitaxially growing a piezoelectric layer on the decomposition layer, wherein the piezoelectric layer is formed of a piezoelectric material, and wherein an energy gap of the III-V compound semiconductor material is less than an energy gap of the piezoelectric material; forming a first electrode on a first surface of the piezoelectric layer; providing a support substrate; bonding the first electrode and the support substrate, wherein a bonding interface is present between the first electrode and the support substrate; removing the growth substrate; and forming a second electrode on a second surface of the piezoelectric layer that is opposite the first surface.

In accordance with other embodiments, an acoustic wave device is provided. The acoustic wave device includes a substrate, a first electrode on the substrate, a piezoelectric layer on the first electrode, and a second electrode on the piezoelectric layer. A bonding interface is present between the first electrode and the substrate. A full width at half maximum (FWHM) in an X-ray diffraction pattern of crystal plane <002> of the piezoelectric layer is between 10 arc-sec and 3600 arc-sec.

In accordance with other embodiments, an acoustic wave device is provided. The acoustic wave device includes a substrate, a support layer, a piezoelectric layer, and a first electrode. The support layer is on the substrate and has a cavity. The piezoelectric layer is on the support layer. The piezoelectric layer includes AlN, ScAlN, or a combination thereof. A full width at half maximum (FWHM) in an X-ray diffraction pattern of crystal plane <002> of the piezoelectric layer is between 10 arc-sec and 3600 arc-sec. The first electrode is on the piezoelectric layer.

In accordance with other embodiments, a method for manufacturing an acoustic wave device is provided. The method includes the following steps: forming a decomposition layer on a growth substrate; forming a piezoelectric material layer on the decomposition layer; forming a support layer on a first surface of the piezoelectric material layer; providing a support substrate; bonding the support layer and the support substrate, wherein a bonding interface is present between the support layer and the support substrate; removing the growth substrate and the decomposition layer; forming a first electrode on a second surface of the piezoelectric material layer that is opposite to the first surface; etching a portion of the piezoelectric material layer to form a piezoelectric layer; and removing a portion of the support layer to form a cavity between the piezoelectric layer and the support layer.

In accordance with other embodiments, a method for manufacturing an acoustic wave device is provided. The method includes the following steps: epitaxially growing a first piezoelectric material layer on a support substrate; forming a first electrode on the first piezoelectric material layer; etching a portion of the first piezoelectric material layer to form a piezoelectric layer and to expose a portion of the support substrate; and etching the portion of the support substrate to form a cavity in the support substrate, wherein the cavity is between the support substrate and the first piezoelectric material layer.

### BRIEF DESCRIPTION OF THE DRAWINGS

Aspects of the present application are understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-5 illustrate cross-sectional views of an acoustic wave device at various intermediate stages of its manufacturing process according to some embodiments of the application.

FIGS. 6A-6F are cross-sectional views of different embodiments illustrating bonding of the first electrode and the support substrate in accordance with some embodiments of the application.

FIGS. 7 and 8 illustrate cross-sectional views of the subsequent processes of removing the growth substrate and the decomposition layer and forming the second electrode according to some embodiments of the application.

FIG. 9 is a cross-sectional view of an acoustic wave device in accordance with other embodiments of the application.

FIGS. 10 and 11 illustrate cross-sectional views of an acoustic wave device having a cavity at various intermediate stages of its manufacturing process according to other embodiments of the application.

FIGS. 12A-12F are cross-sectional views of different embodiments illustrating bonding of the first electrode and the support substrate in accordance with other embodiments of the application.

FIGS. 13-15 illustrate cross-sectional views of the subsequent processes of removing the growth substrate and the decomposition layer and forming the second electrode according to other embodiments of the application.

FIG. 16 is a cross-sectional view of an acoustic wave device in accordance with other embodiments of the application.

FIG. 17 is a frequency response pattern of a return loss test using the acoustic wave device of the embodiments of the application.

FIG. 18 illustrates a cross-sectional view of an acoustic wave device having interdigital electrodes at various intermediate stages of its manufacturing process according to other embodiments of the application.

FIGS. 19A-19E are cross-sectional views of different embodiments illustrating bonding of the support layer and the support substrate.

FIGS. 20-22 illustrate cross-sectional views of the following processes of manufacturing the acoustic wave device according to some embodiments of the application.

FIGS. 23-26 illustrate cross-sectional views of an acoustic wave device having a piezoelectric layer formed by different methods according to some further embodiments of the application.

FIGS. 27-30 illustrate cross-sectional views of an acoustic wave device only having a second electrode at various intermediate stages of its manufacturing process according to other embodiments of the application.

FIGS. 31-33 illustrate cross-sectional views of an acoustic wave device at various intermediate stages of its manufacturing process using a support substrate as a growth substrate according to other embodiments of the application.

### DETAILED DESCRIPTION OF THE DISCLOSURE

An acoustic wave device and manufacturing method thereof provided in the application is described in detail in the following description. It should be appreciated that the following application provides many different embodiments, or examples, for implementing different features of the application. Specific examples of elements and arrangements are described below to clearly describe the application in a simple manner. These are, of course, merely examples and are not intended to be limiting. In addition, different embodiments may use like and/or corresponding reference numerals to denote like and/or corresponding elements for clarity. It is contemplated that the elements and features of one embodiment may be beneficially incorporated in another embodiment without further recitation.

In addition, additional layers/structures or steps may be incorporated into the following embodiments. For example, “the formation of a second layer/structure on a first layer/structure” in the description may include embodiments in which the first and second layers/features are formed in direct contact, and may also include embodiments in which the first and second layers/features are formed in indirect contact. That is, additional layers/structures may be formed between the first and second layers/structures. Besides, the spatial relationship between the first layer/structure and the second layer/structure may change according to the operation or usage of the device. The first layer/structure is not limited to a single layer or a single structure. The first layer may include multiple sub-layers, and the first structure may include multiple sub-structures.

In addition, spatial terms in the application, such as “under”, “beneath”, “below”, “lower”, “on”, “over,” “above,” “upper,” “top,” “bottom” and the like, may be used herein for ease of description to describe the spatial relationship between one element or feature's and another element(s) or feature(s) as illustrated in the figures. The spatial terms are intended to encompass different orientations of the acoustic wave device in use or operation in addition to the orientation depicted in the figures. The acoustic wave device may be otherwise oriented (rotated 90 degrees or at other orientations) and the spatial descriptions used herein may likewise be interpreted accordingly.

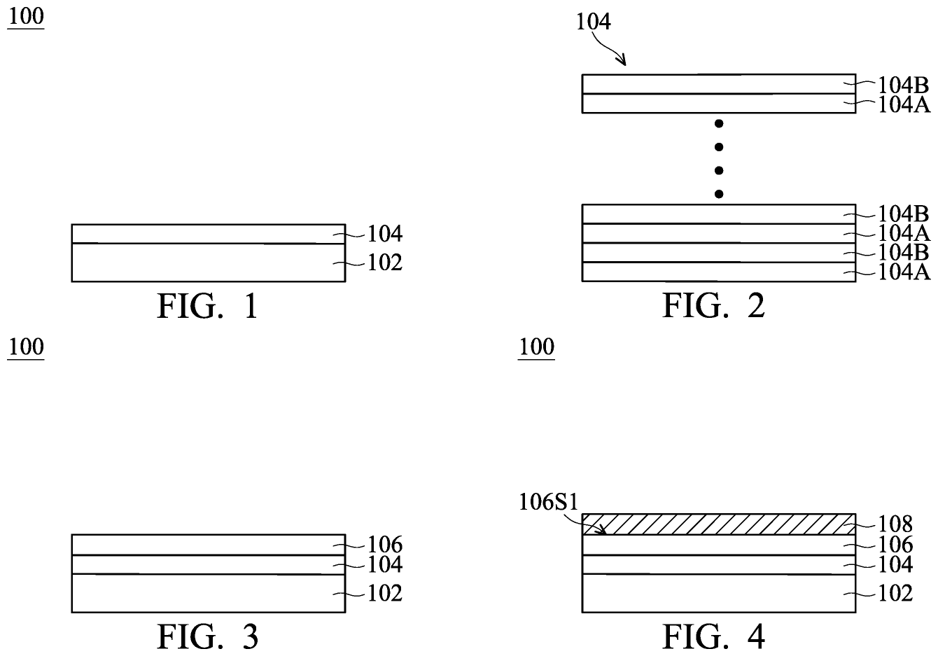

FIGS. 1-5 illustrate cross-sectional views of an acoustic wave device 100 at various intermediate stages of its manufacturing process according to some embodiments of the application. Referring to FIGS. 1 and 3, a growth substrate 102 is provided. A decomposition layer 104 is formed on the growth substrate 102, and a piezoelectric layer 106 is grown on the decomposition layer 104. In some embodiments, the growth substrate 102 may be an epitaxial substrate whose material may include silicon, silicon carbide, sapphire, gallium nitride, aluminum gallium nitride, or a combination thereof.

Referring to FIG. 2, the decomposition layer 104 includes a bulk layer or a plurality of sub-layers. In one embodiment, the sub-layers include a superlattice structure. In one embodiment, the decomposition layer 104 may reduce lattice mismatch between the growth substrate 102 and epitaxial layers formed subsequently, such as the piezoelectric layer 106. As such, the piezoelectric layer 106 may have better crystal quality. The material of the decomposition layer 104 includes a compound semiconductor material, such as a III-V compound semiconductor material. In the embodiments in which the decomposition layer 104 is a bulk-layered structure, a group III element in the III-V compound semiconductor material forming the bulk-layered structure may gradually change in composition as the bulk-layered structure grows. In one embodiment, the group III element may gradually increase or decrease in composition as the bulk-layered structure grows. In the embodiments in which the decomposition layer 104 is a superlattice structure, the superlattice structure is formed of a stacking layer of III-V compound semiconductor materials. The energy gap of the III-V compound semiconductor materials forming the bulk-layered structure or the superlattice structure is less than that of the piezoelectric material subsequently forming the piezoelectric layer 106. In some embodiments, as shown in FIG. 2, the decomposition layer 104 may include a stack of alternating first semiconductor layers 104A and second semiconductor layers 104B. The bottommost layer is the first semiconductor layer 104A, and the topmost layer is the second semiconductor layer 104B. The dots in FIG. 2 means the first semiconductor layer 104A and the second semiconductor layer 104B that have the same structure and stack alternately and repeatedly. In some embodiments, a group III element in the III-V compound semiconductor material forming the first semiconductor layer 104A may gradually change in composition as the superlattice structure grows, and/or a group III element in the III-V compound semiconductor material forming the second semiconductor layer 104B may gradually change in composition as the superlattice structure grows. In some embodiments, the number of the film pairs formed of the first semiconductor layer 104A and the second semiconductor layer 104B may be between about 2 and about 100. In some specific embodiments, the number of the film pairs formed of the first semiconductor layer 104A and the second semiconductor layer 104B may be between about 2 and about 15. In some embodiments, the decomposition layer 104 may be formed by metal organic chemical vapor deposition (MOCVD), molecular beam epitaxy (MBE), liquid phase epitaxy (LPE), vapor phase epitaxy (VPE), or combinations thereof.

In the embodiments in which the decomposition layer 104 is a superlattice structure, the first semiconductor layer 104A may include AlₓGa₁₋ₓN, and the second semiconductor layer 104B may include Al_{y}Ga_{1-y}N, wherein y is greater than x, and each of x and y ranges from about 0 to about 1.0. It should be noted that the aforementioned range of between about 0 and about 1.0 means that each of x and y may be 0 or 1.0. In some specific embodiments, x of AlₓGa₁₋ₓN in the first semiconductor layer 104A may be between about 0 and about 0.5, and they of Al_{y}Ga_{1-y}N in the second semiconductor layer 104B may be between about 0.2 and about 1.0. It should be noted that the range of between about 0 and about 0.5 for x means that x may be 0 or 0.5, and the range of between about 0.2 and about 1.0 for y means that y may be 0.2 or 1.0. In addition, in some embodiments, the thickness of the first semiconductor layer 104A may be between about 0.5 nm and about 10 nm, such as about 2 nm, and the thickness of the second semiconductor layer 104B may be between about 1 nm and about 20 nm, such as about 5 nm. In the embodiments in which the decomposition layer 104 is a bulk-layered structure with a gradient composition, the III-V compound semiconductor material of the bulk-layered structure close to the growth substrate 102 includes AlₓGa₁₋ₓN, and the III-V compound semiconductor material of the bulk-layered structure close to the piezoelectric layer 106 includes Al_{y}Ga_{1-y}N, wherein y is greater than x, and 0≤x<1 and 0<y≤1. Al in the III-V compound semiconductor material gradually increases in the direction of the thickness of the bulk-layered structure; that is, Al gradually increases from x to y. In some embodiments, the lattice constant of the Al_{y}Ga_{1-y}N material in the superlattice structure or the bulk-layered structure is closer to that of the piezoelectric layer 106 than that of the AlₓGa₁₋ₓN. Accordingly, the crystal quality of the piezoelectric layer 106 may be increased because of lattice match.

In accordance with some embodiments, an additional buffer layer (not shown) may be formed on the growth substrate 102, and the decomposition layer 104 may be formed on the buffer layer. In some embodiments, the thickness of the buffer layer may be between about 0.1 μm and about 7 μm. In some embodiments, the material of the buffer layer may include aluminum nitride or gallium nitride. The formation of the buffer layer on the growth substrate 102 may increase crystal quality of the subsequently formed decomposition layer 104, thereby resulting in the piezoelectric layer 106 with better crystal quality.

In some embodiments, the piezoelectric layer 106 may be formed by metal organic chemical vapor deposition, molecular beam epitaxy, liquid phase epitaxy, vapor phase epitaxy, or combinations thereof. In some embodiments, the piezoelectric layer 106 may be a monocrystalline layer. In other embodiments, the piezoelectric layer 106 may be a polycrystalline layer. In some embodiments, the piezoelectric layer 106 may be a combination of a monocrystalline layer and a polycrystalline layer. For example, the piezoelectric layer 106 may be transformed from a polycrystalline layer into a monocrystalline layer in the growth direction. In some embodiments, the piezoelectric material of the piezoelectric layer 106 may include a semiconductor material, a ceramic material, or a film material. The semiconductor material may include aluminum nitride, the ceramic material may include lead zirconate titanate (PZT, also known as the piezoelectric ceramic), and the film material may include zinc oxide. In some embodiments, the piezoelectric material of the piezoelectric layer 106 may include scandium (Sc) or may be doped with scandium (Sc). In some specific embodiments, the piezoelectric material of the piezoelectric layer 106 may include aluminum nitride, which has an energy gap of about 6.2 eV. In some embodiments, the thickness of the piezoelectric layer 106 may be between about 0.05 μm and about 10 μm. In some specific embodiments, the thickness of the piezoelectric layer 106 may be between about 0.1 μm and about 3.0 μm.

As stated above, the energy gap of the III-V compound semiconductor material forming the bulk-layered structure or the superlattice structure of the decomposition layer 104 may be less than that of the piezoelectric material forming the piezoelectric layer 106. In particular, in the embodiments in which the decomposition layer 104 is a bulk-layered structure, the bulk-layered structure has a gradient composition, and the energy gap of a portion of the bulk-layered structure is less than that of another portion of the bulk-layered structure. As a result, the portion of the bulk-layered structure with a lower energy gap may tend to absorb laser light in the following laser lift-off process, and it may be decomposed, and then detached from the underlying layers after absorbing the laser light energy. The location of the portion with lower energy gap in the bulk-layered structure may be designed according to actual need. In the embodiments in which the decomposition layer 104 is a superlattice structure, the energy gap of the second semiconductor layer 104B in the superlattice structure of the decomposition layer 104 may be between the energy gap of the piezoelectric material of the piezoelectric layer 106 and the energy gap of the first semiconductor layer 104A. In the superlattice structure of the decomposition layer 104, the bottommost layer is the first semiconductor layer 104A. The lower energy gap of the first semiconductor layer 104A than that of the second semiconductor layer 104B is conducive to absorption of laser light for the first semiconductor layer 104A in the following lift-off process. Therefore, the first semiconductor layer 104A may be decomposed, and then detached from the underlying layers after absorbing the laser light energy. On the other hand, in the superlattice structure of the decomposition layer 104, the topmost layer is the second semiconductor layer 104B. The second semiconductor layer 104B has a similar lattice constant to that of the piezoelectric layer 106, thereby coordinating the lattice difference between the growth substrate 102 and the piezoelectric layer 106. Therefore, the piezoelectric layer 106 formed on the second semiconductor layer 104B may have better crystal quality and surface flatness.

The crystal quality of the piezoelectric layer 106 may be measured by using an X-ray diffraction pattern of the crystal plane <002>. A smaller full width at half maximum (FWHM) in the X-ray diffraction pattern suggests better crystal quality of the measured material. The piezoelectric layer 106 provided by the embodiments of the application may have a full width at half maximum of between about 10 arc-sec and about 1000 arc-sec in the X-ray diffraction pattern of the crystal plane <002>. In some specific embodiments, the full width at half maximum of the piezoelectric layer 106 in the X-ray diffraction pattern of the crystal plane <002> may be between about 10 arc-sec and about 500 arc-sec. In other embodiments, the full width at half maximum of the piezoelectric layer 106 in the X-ray diffraction pattern of the crystal plane <002> may be between about 10 arc-sec and about 3600 arc-sec. Compared to other piezoelectric layers with the same thickness formed by other processes, since the piezoelectric layer of the embodiments of the application has better crystal quality, the piezoelectric layer may have a smaller full width at half maximum in the X-ray diffraction pattern of the crystal plane <002>. The piezoelectric layer with better crystal quality may have better electromechanical coupling efficiency to efficiently convert electrical energy into mechanical energy or convert mechanical energy into electrical energy.

Next, referring to FIG. 4, a first electrode 108 is formed on the first surface 106S1 of the piezoelectric layer 106. The material of the first electrode 108 may include a metal, such as molybdenum (Mo), aluminum (Al), tungsten (W), titanium (Ti), titanium-tungsten alloy (TiW), rubidium (Ru), silver (Ag), copper (Cu), gold (Au), platinum (Pt), or combinations thereof. The material for the first electrode 108 may be deposited by physical vapor deposition (PVD), atomic layer deposition (ALD), metal organic chemical vapor deposition, other suitable deposition techniques, or combinations thereof. In some embodiments, the thickness of the first electrode 108 may be between about 0.01 μm and about 5 μm.

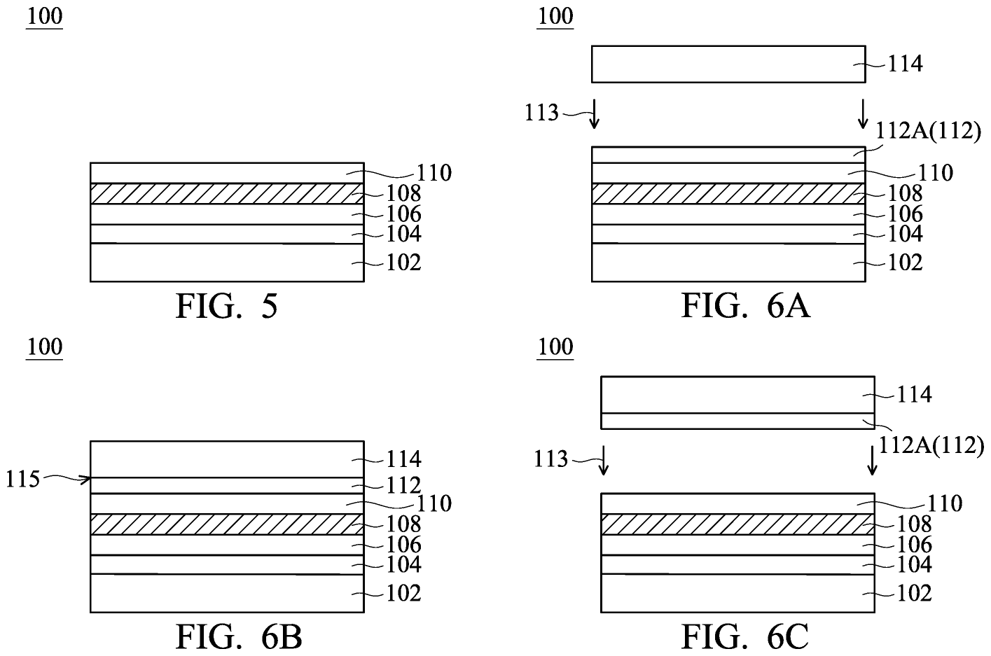

Next, referring to FIG. 5, according to some embodiments of the application, an acoustic wave reflective structure may be formed on the first electrode 108. In this embodiment, the acoustic wave reflective structure includes an acoustic wave reflective layer 110, and the acoustic wave reflective layer 110 may have a distributed Bragg reflector (DBR) structure. It should be noted that, although not explicitly shown, the acoustic wave reflective layer 110 of the embodiment of the application may include alternating layers formed by stacking an acoustic wave reflective material layer with low acoustic impedance and an acoustic wave reflective material layer with high acoustic impedance. The acoustic wave reflective material layer with high acoustic impedance has higher acoustic impedance than the acoustic wave reflective material layer with low acoustic impedance does. In addition, there is no particular limitation on the number of film pairs of the alternating layers in the acoustic wave reflective layer 110, and any suitable numbers of acoustic wave reflecting material layers with low acoustic impedance and acoustic wave reflecting material layers with high acoustic impedance may be deposited according to product requirements. In some embodiments, the material of the acoustic wave reflective material layer with low acoustic impedance may include a metal or a non-metallic material. For example, the metal may include aluminum, titanium, or combinations thereof, and the non-metallic material may include a semiconductor material such as silicon, or a dielectric material such as silicon oxide (SiO₂), silicon nitride (SiNₓ), silicon oxynitride (SiON), titanium oxide (TiO₂), magnesium nitride (MgN), or combinations thereof. In some embodiments, the material of the acoustic wave reflective material layer with high acoustic impedance may include metal, such as molybdenum, tungsten, nickel, platinum, gold, an alloy thereof, or combinations thereof. Furthermore, in some embodiments, the thickness of the acoustic wave reflective layer 110 may be between about 0.1 μm and about 50 μm.

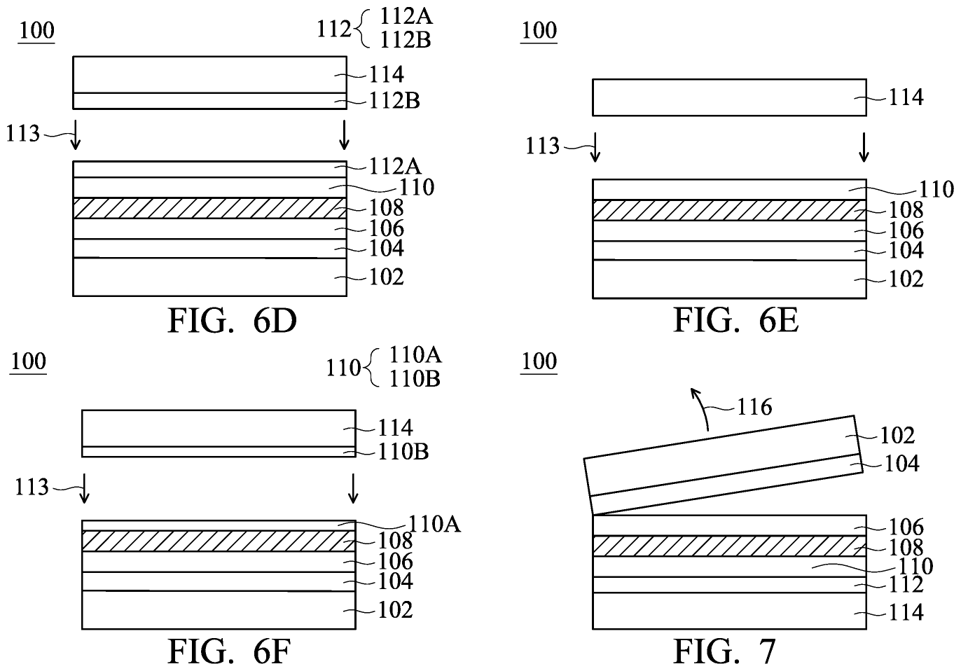

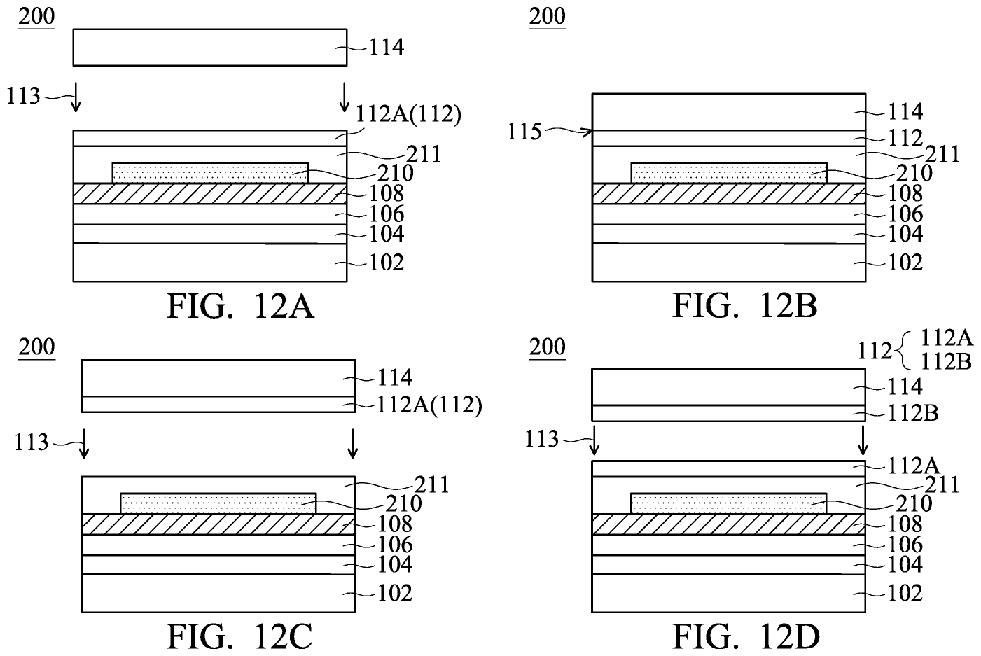

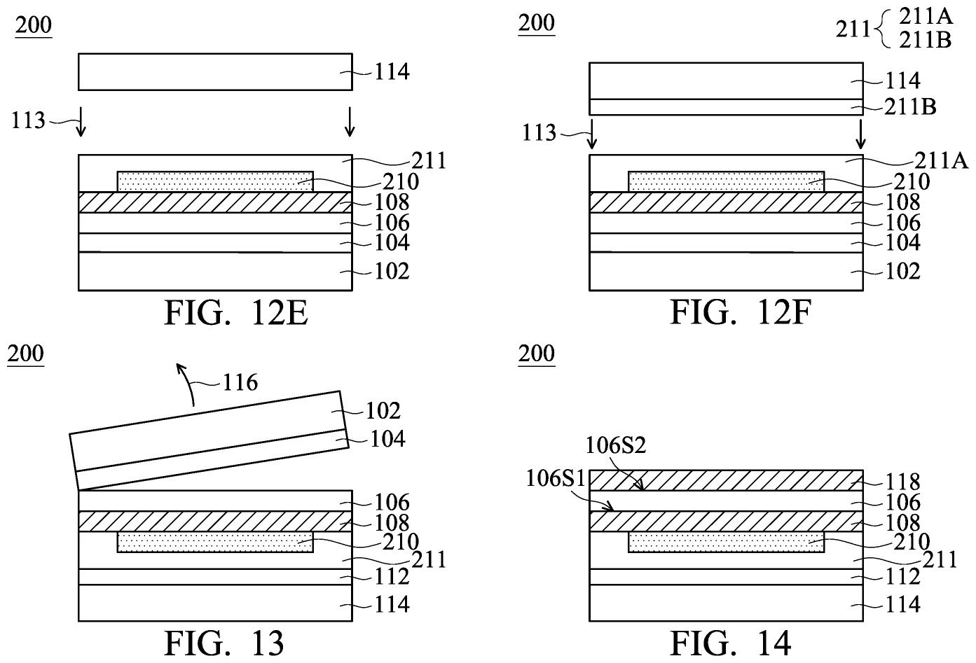

FIGS. 6A-6F and 12A-12F are cross-sectional views of different embodiments illustrating bonding of the first electrode 108 and the support substrate 114 in the processes for forming the acoustic wave devices 100 and 200. By the processes provided by the embodiments of the application, the first electrode 108 and the support substrate 114 are bonded by a bonding process 113, and a bonding interface 115 is present between the first electrode 108 and the support substrate 114. In some embodiments, the bonding interface 115 between the first electrode 108 and the support substrate 114 may be a metallic bonding interface. In some embodiments, the bonding interface 115 between the first electrode 108 and the support substrate 114 may be a covalently bonded interface. In addition, in some embodiments, the bonding process 113 may be performed at a temperature of between about 100° C. and about 400° C. Owing to the low temperature for the covalent bonding of the bonding process 113, two parts of the acoustic wave device 100 may not have severe warpage resulted from the difference in coefficients of thermal expansion after being bonded to each other. Furthermore, the bonding interface 115 formed by the covalent bonding of the bonding process 113 may be flatter, thereby increasing bonding adhesion in the acoustic wave device 100.

Referring to FIG. 6A, in the embodiments in which the acoustic wave device 100 has the acoustic wave reflective layer 110, a first bonding layer 112A may be formed on the acoustic wave reflective layer 110, and then the acoustic wave reflective layer 110 and the support substrate 114 may be bonded to each other by the bonding process 113. As shown in FIG. 6A, the acoustic wave reflective layer 110 and the support substrate 114 may be bonded to each other through the first bonding layer 112A, and the first bonding layer 112A is the bonding layer 112 after the bonding step. Referring to FIG. 6B, after the bonding step, the bonding interface 115 is present between the support substrate 114 and the bonding layer 112.

In some embodiments, the material of the first bonding layer 112A may include an insulating material, a semiconductor material, a metal oxide material, or other suitable materials. For example, the insulating material may include silicon oxide (Sift), benzocyclobutene (BCB), silicon nitride (SiNₓ), wax, bonding glue (such as epoxy resin, UV curing glue, and the like), photoresist, or a combination thereof the semiconductor material may include polysilicon; the metal oxide material may include aluminum oxide, indium tin oxide, or a combination thereof, and other suitable materials may include aluminum nitride, lead zirconate titanate, or a combination thereof. In some embodiments, the material of the support substrate 114 may include a semiconductor material or an insulating material. The semiconductor material may include silicon, silicon carbide, aluminum nitride, gallium nitride, aluminum gallium nitride, or combinations thereof, and the insulating material may include sapphire, glass, polyimide (PI), or combinations thereof.

Compared with the existing bonding process using metallic materials, since the bonding process of the acoustic wave device utilizes the aforementioned materials, the bonding interface is a non-metallic bonding interface, such as a covalently bonded interface or an adhesive bonding interface. As such, the bonding process may be performed at a lower temperature to prevent the acoustic wave device from warpage caused by high temperature of the bonding process. Accordingly, the bonding interface formed by the bonding process may be flatter, and bonding adhesion in the acoustic wave device may be increased. In addition, the piezoelectric layer of the acoustic wave device may generate an electrical signal when operating, and the use of the aforementioned materials with higher resistance for bonding may also prevent loss of the electrical signal from the acoustic wave device, thereby enhancing the signal strength of the acoustic wave device.

Referring to FIG. 6C, in other embodiments in which the acoustic wave reflective layer 110 is formed in the acoustic wave device 100, the first bonding layer 112A may be formed on the support substrate 114, and then the bonding process 113 is used to bond the acoustic wave reflective layer 110 and the support substrate 114. As shown in FIG. 6C, the acoustic wave reflective layer 110 and the support substrate 114 are bonded to each other through the first bonding layer 112A, and the first bonding layer 112A is the bonding layer 112. After the bonding step, a bonding interface is present between the acoustic wave reflective layer 110 and the bonding layer 112. The material of the acoustic wave reflective layer 110 may be the same as or similar to that of the bonding layer 112, which is not repeated herein. In other embodiments, different materials may be also used for the acoustic wave reflective layer 110 and the bonding layer 112. In some embodiments, the materials of the acoustic wave reflective layer 110 and the bonding layer 112 are metallic materials, and thus the bonding interface is formed with metallic bonding. In some embodiments, the materials of the acoustic wave reflective layer 110 and the bonding layer 112 are non-metallic materials, and thus the bonding interface is formed by non-metallic bonding, such as covalently bonded interface or adhesive bonding interface.

Referring to FIG. 6D, in other embodiments in which the acoustic wave reflective layer 110 is formed in the acoustic wave device 100, in addition to the formation of the first bonding layer 112A on the acoustic wave reflective layer 110, a second bonding layer 112B may be further formed on the support substrate 114. Next, the acoustic wave reflective layer 110 is bonded to the support substrate 114 by the bonding process 113, and the acoustic wave reflective layer 110 and the support substrate 114 are bonded to each other through the first bonding layer 112A and the second bonding layer 112B. However, the application is not limited thereto. In other embodiments, the first bonding layer 112A may be formed on the support substrate 114, and then the second bonding layer 112B is formed on the acoustic wave reflective layer 110. Subsequently, the acoustic wave reflective layer 110 is bonded to the support substrate 114 by the bonding process 113. The material for the second bonding layer 112B may be the same as or similar to that for the first bonding layer 112A, which is not repeated herein. In other embodiments, the different materials may be used for the first bonding layer 112A and the second bonding layer 112B. In FIG. 6D, after completing the bonding step, the first bonding layer 112A and the second bonding layer 112B may form the bonding layer 112, and thus the bonding interface may be present within the bonding layer 112. In some embodiments, the materials of the first bonding layer 112A and the second bonding layer 112B are metallic materials, thereby forming the bonding interface with metallic bonding. In some embodiments, the materials of the first bonding layer 112A and the second bonding layer 112B are non-metallic materials, thereby forming the bonding interface with non-metallic bonding, such as a covalently bonded interface or an adhesive bonding interface.

Referring to FIG. 6E, in some embodiments, no additional bonding layer may be formed, and the acoustic wave reflective layer 110 and the support substrate 114 may be directly bonded to each other by the bonding process 113. After the bonding step, the bonding interface is present between the acoustic wave reflective layer 110 and the support substrate 114. The material of the acoustic wave reflective layer 110 may be the same as or similar to that of the support substrate 114, which is not repeated herein. In other embodiments, different materials may be used for the acoustic wave reflective layer 110 and the support substrate 114. In some embodiments, the materials of the acoustic wave reflective layer 110 and the support substrate 114 are metallic materials, thereby forming the bonding interface with metallic bonding. In some embodiments, the materials of the acoustic wave reflective layer 110 and the support substrate 114 are non-metallic materials, thereby forming the bonding interface with non-metallic bonding, such as a covalently bonded interface or an adhesive bonding interface.

Referring to FIG. 6F, in accordance with other embodiments of the application, a portion of the acoustic wave reflective layer 110, the acoustic wave reflective material layer 110A, may be formed on the first electrode 108, and another portion of the acoustic wave reflective layer 110, the acoustic wave reflective material layer 110B, may be formed on the support substrate 114. Specifically, a portion of one acoustic wave reflective material layer with low acoustic impedance in the alternating layers of the acoustic wave reflective layer 110 may be formed on the first electrode 108, such as the acoustic wave reflective material layer 110A in FIG. 6F, and then another portion of the acoustic wave reflective material layer with low acoustic impedance is formed on the support substrate 114, such as the acoustic wave reflective material layer 110B in FIG. 6F. It should be appreciated that the acoustic wave reflective material layers 110A and 110B may further include the acoustic wave reflective material layers with high impedance in the acoustic wave reflective layer 110. In some embodiments, the thickness of the acoustic wave reflective material layer 110A formed on the first electrode 108 may be greater than that of the acoustic wave reflective material layer 110B formed on the support substrate 114, thereby enabling the acoustic wave device 100 to have better acoustic reflectivity. Afterwards, the first electrode 108 is bonded to the support substrate 114 by the bonding process 113, and the first electrode 108 and the support substrate 114 are bonded to each other through the acoustic wave reflective material layers 110A and 110B. After the bonding step, the acoustic wave reflective material layers 110A and 110B may form the complete acoustic wave reflective layer 110, thereby forming a bonding interface within the acoustic wave reflective layer 110. The materials of the acoustic wave reflective material layers 110A and 110B may be the same of similar, which are not repeated herein. In other embodiments, the materials of the acoustic wave reflective material layers 110A and 110B may be different. In some embodiments, the materials of the acoustic wave reflective material layers 110A and 110B are metallic materials. Bonding of the acoustic wave reflective material layers 110A and 110B generates the bonding interface with metallic bonding. In some embodiments, the materials of the acoustic wave reflective material layers 110A and 110B are non-metallic materials, thereby forming the bonding interface with non-metallic bonding, such as a covalently bonded interface or an adhesive bonding interface.

Since any of the acoustic wave reflective material layers with low impedance in the alternating layers of the acoustic wave reflective layers 110 may be split into two parts for the bonding process, the bonding interface can be present within any of the acoustic wave reflective material layers with low impedance in the alternating layers of the acoustic wave reflective layers 110. In some embodiments, the material of the acoustic wave reflective material layer with low impedance that is split into two parts is a metallic material, thereby forming the bonding interface with metallic bonding. In some embodiments, the material of the acoustic wave reflective material layer with low impedance that is split into two parts is a non-metallic material, thereby forming the bonding interface with non-metallic bonding, such as a covalently bonded interface or an adhesive bonding interface. By performing the bonding process according to the embodiment shown in FIG. 6F, no additional bonding layer is required, and the bonding process may be performed at a lower temperature to prevent the acoustic device 100 from severe warpage during the bonding process 113.

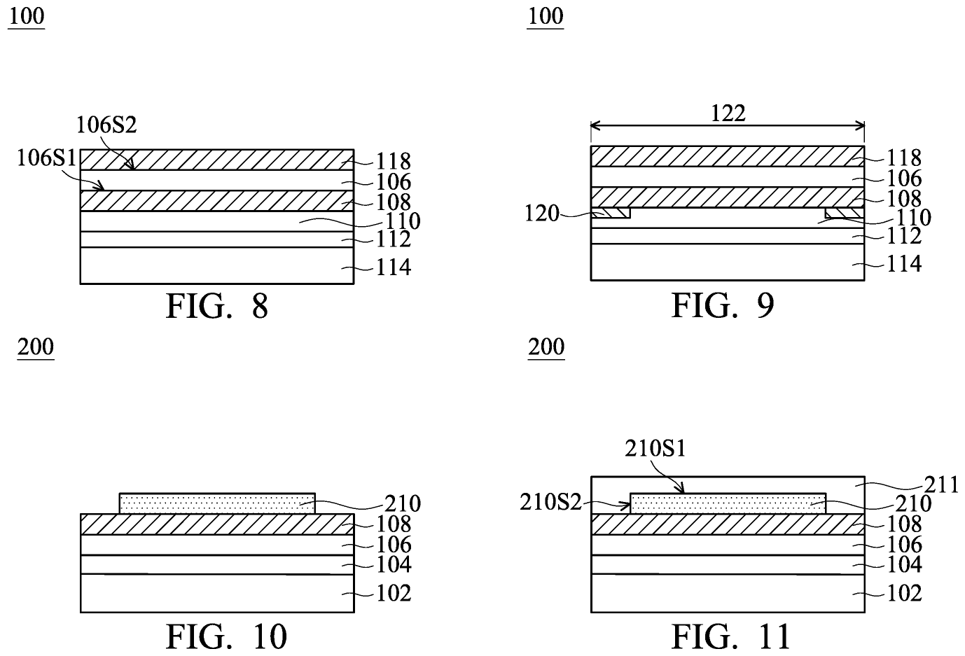

FIGS. 7 and 8 illustrate cross-sectional views of the subsequent processes of removing the growth substrate 102 and the decomposition layer 104 after bonding the first electrode 108 and the support substrate 114, and forming a second electrode 118 according to some embodiments of the application. The embodiment in which the acoustic wave device 100 includes the acoustic wave reflective layer 110 and the bonding layer 112 is merely an example for illustration, but the application is not limited thereto. The following processes may be applicable to any of the aforementioned embodiments. Referring to FIG. 7, after bonding the first electrode 108 and the support substrate 114, the growth substrate 102 and the decomposition layer 104 are removed to expose the piezoelectric layer 106. In some embodiments, the step for removing the growth substrate 102 may include a laser lift-off process 116. The wavelength of the laser light used in the laser lift-off process 116 may be between about 50 nm and about 400 nm. In some embodiments, a laser light source that has an energy gap that is less than those of the growth substrate 102 and the piezoelectric layer 106 and is greater than that of the decomposition layer 104 may be selected for the laser lift-off process 116. In one embodiment, the laser light with an energy gap between those of the first semiconductor layer 104A and the second semiconductor layer 104B is used to irradiate the decomposition layer 104. When the energy gap of the laser light is less than that of the second semiconductor layer 104B and greater than that of the first semiconductor layer 104A, most energy from the laser light may be absorbed by the first semiconductor layer 104A, and the first semiconductor layer 104A may be decomposed. Therefore, the first semiconductor layer 104A may be detached from the underlying layers (such as the growth substrate 102). In some embodiments, after removing the growth substrate 102, a portion of the decomposition layer 104 remains on the piezoelectric layer 106, and the remaining portion of the decomposition layer 104 may be removed by suitable removal processes, such as dry etching, wet etching, and/or other suitable processes. For example, the dry etching process may include plasma etching (PE), reactive ion etching (RIE), inductively coupled plasma reactive ion etching (ICP-RIE), and the like, and may be performed by using plasma, gas, or a combination thereof. The gas may include oxygen-containing gas, fluorine-containing gas (such as hydrogen fluoride, carbon tetrafluoride, sulfur hexafluoride, difluoromethane, fluoroform, and/or hexafluoroethane), chlorine-containing gas (such as chlorine, chloroform, carbon tetrachloride, and/or boron trichloride), bromine-containing gases (such as hydrogen bromide and/or bromoform), iodine-containing gas, and/or combinations thereof. For example, the wet etching process may be performed by using acidic or alkaline solutions, or other suitable wet etching chemicals. The acidic solution may include hydrofluoric acid, phosphoric acid, hydrochloric acid, nitric acid, acetic acid, or combinations thereof. The alkaline solution may include a solution containing potassium hydroxide, ammonia, hydrogen peroxide, or a combination thereof.

Next, referring to FIG. 8, the second electrode 118 is formed on a second surface 106S2 of the piezoelectric layer 106. The second surface 106S2 is opposite the first surface 106S1. The material and the process for the second electrode 118 may be the same as those for the first electrode 108, which are not repeated herein. Since the decomposition layer 104 is formed during the process of forming the acoustic wave device 100, lattice mismatch between the growth substrate 102 and the piezoelectric layer 106 may be reduced, thus resulting in better crystal quality and surface flatness of the piezoelectric layer 106 formed on the decomposition layer 104. In addition, during the removal of the growth substrate 102 by irradiating the decomposition layer 104 by using laser light, a portion of the material of the decomposition layer 104 may remain on the piezoelectric layer 106 after decomposing of the decomposition layer 104. Suitable removal processes may be further adopted to remove the remaining material. In some embodiments, the first semiconductor layer 104A of the decomposition layer 104 may include AlₓGa₁₋ₓN. Adjusting the composition of the material may avoid the remaining material of the decomposition layer 104 on the piezoelectric layer 106, or may enable a removal process to easily remove the remaining material without causing damage to the surface of the piezoelectric layer 106. As such, flatness of the surface of the piezoelectric layer 106 that is adjacent to the decomposition layer 104 may be maintained. According to some embodiments of the application, the first surface 106S1 of the piezoelectric layer 106 that is in contact with the first electrode 108 and the second surface 106S2 of the piezoelectric layer 106 that is in contact with the second electrode 118 are flat surfaces. In some embodiments, the roughness (Ra) of the first surface 106S1 and the second surface 106S2 of the piezoelectric layer 106 may be between about 0.01 nm and about 5 nm. In some specific embodiments, the roughness (Ra) of the first surface 106S1 and the second surface 106S2 of the piezoelectric layer 106 may be between about 0.01 nm and about 1 nm.

Still referring to FIG. 8, in accordance with the embodiments of the application, the acoustic wave device 100 may include the support substrate 114, the first electrode 108 above the support substrate 114, the piezoelectric layer 106 on the first electrode 108, and the second electrode 118 on the piezoelectric layer 106. The bonding interface is present between the support substrate 114 and the first electrode 108. According to some embodiments of the application, the bonding interface may be located between the support substrate 114 and the bonding layer 112 (the bonding interface 115 shown in the embodiments of FIG. 6B), between the bonding layer 112 and the acoustic wave reflective layer 110 (the embodiments shown in FIG. 6C), within the bonding layer 112 (the embodiments shown in FIG. 6D), between the acoustic wave reflective layer 110 and the support substrate 114 (the embodiments shown in FIG. 6E), or within the acoustic wave reflective layer 110 (the embodiments shown in FIG. 6F). In addition, the piezoelectric layer 106 may have a full width at half maximum of between about 10 arc-sec and about 1000 arc-sec in the X-ray diffraction pattern of the crystal plane <002>. Accordingly, in accordance with the embodiments provided in FIGS. 1-5, 6A-6F, 7, and 8, the piezoelectric layer 106 that is formed with the decomposition layer 104 may have better crystal quality and surface flatness, and thus the piezoelectric layer 106 may have better electromechanical coupling efficiency, and overall structural stability of the acoustic wave device 100 may be increased. On the other hand, the non-metallic bonding process with the aforementioned bonding materials, such as a covalent bonding process or an adhesive bonding process, may prevent the acoustic wave device 100 from warpage resulted from high temperature, and may result in a flatter bonding interface with non-metallic bonding, such as a covalently bonded interface or an adhesive bonding interface. Therefore, structural stability of the acoustic wave device 100 may be increased.

Next, referring to FIG. 9, FIG. 9 is a cross-sectional view of the acoustic wave device 100 according to other embodiments of the application. In the embodiments shown in FIG. 9, the acoustic wave device 100 further includes a tuning layer 120 between the support substrate 114 and the first electrode 108. The tuning layer 120 is in direct contact with a portion of the first electrode 108. Specifically, prior to the bonding process of the first electrode 108 and the support substrate 114, the tuning layer 120 may be formed on a portion of the first electrode 108.

In some specific embodiments, as shown in FIG. 9, the tuning layer 120 may be formed below a portion of the first electrode 108 that is located on the margin of an active region 122 of the acoustic wave device 100. The term “active region” used herein means the region where resonance occurs during operation of the acoustic wave device mainly with a piston mode. Disposing the tuning layer 120 below a portion of the first electrode 108 that is located on the margin of the active region 122 of the acoustic wave device 100 may suppress the effect caused by the spurious mode during operation of the acoustic wave device 100, thereby reducing insertion loss of the acoustic wave device 100 and improving interference of the spurious mode in the bandwidth of the acoustic wave device 100.

In some embodiments, the material of the tuning layer 120 may include molybdenum (Mo), aluminum (Al), titanium (Ti), titanium tungsten alloy (TiW), rubidium (Ru), silver (Ag), copper (Cu), gold (Au), platinum (Pt) or combinations thereof. In some embodiments, the thickness of the tuning layer 120 may be between about 10 nm and about 500 nm.

In some embodiments, in the structure shown in FIG. 4, the tuning layer 120 can be formed on a portion of the first electrode 108 that is located on the margin of the active region 122 of the acoustic wave device 100 by a photolithography process, such as an etching process or a lift-off process, and then the acoustic wave reflective layer 110 is formed on the first electrode 108 and the tuning layer 120.

FIGS. 10, 11, 12A-12F, and 13-15 illustrate cross-sectional views of an acoustic wave device 200 at various intermediate stages of its manufacturing process according to other embodiments of the application. The forming method and the structures of the growth substrate 102, the decomposition layer 104, the piezoelectric layer 106, and the first electrode 108 in the acoustic wave device 200 are similar to those in the acoustic wave device 100, which are not repeated herein. In the embodiments, the acoustic wave reflective structure formed on the first electrode 108 includes a cavity. Referring to FIG. 10, according to some embodiments of the application, a sacrificial layer 210 may be formed on a portion of the first electrode 108. The sacrificial layer 210 will be removed in the following process to form the cavity in the acoustic wave device 200. The sacrificial layer 210 may be a removable material having etching selectivity with respect to the subsequently formed support layer. In some embodiments, the material of the sacrificial layer 210 may include an inorganic material, an organic material, or a combination thereof. For example, the inorganic material may include an oxide of tetraethoxysilane (TEOS), amorphous silicon (a-Si), phosphosilicate glass (PSG), silicon dioxide, polycrystalline silicon (poly-Si), or combinations thereof. For example, the organic material may include photoresist or other suitable materials. The sacrificial layer 210 can be formed on a predetermined position or region on the first electrode 108 by a suitable process such as a photolithography process and an etching process or other alternative methods. In addition, the material of the sacrificial layer 210 may be deposited by chemical vapor deposition process, atomic layer deposition process, physical vapor deposition process, spin coating process, other suitable processes, or combinations thereof.

Next, referring to FIG. 11, a support layer 211 is formed on the first electrode 108. The support layer 211 covers the upper surface 210S1 and the side surface 210S2 of the sacrificial layer 210. The material of the support layer 211 can be selected from materials with higher etching resistance than the sacrificial layer 210, such as monocrystalline silicon, polycrystalline silicon, amorphous silicon, silicon dioxide, or a combination thereof. In some embodiments, when the material of the sacrificial layer 210 is silicon dioxide or phosphosilicate glass, the material of the support layer 211 can be selected from monocrystalline silicon or polycrystalline silicon. In some embodiments, when the material of the sacrificial layer 210 is amorphous silicon, the material of the support layer 211 can be selected from silicon dioxide.

Next, referring to FIGS. 12A-12F, FIGS. 12A-12F are cross-sectional views of different embodiments illustrating bonding of the first electrode 108 and the support substrate 114 in accordance with different embodiments. In various embodiments shown in FIGS. 12A-12D, the bonding layer 112, the first bonding layer 112A and the second bonding layer 112B of the acoustic wave device 200 may be made of the same or similar materials to those of the bonding layer 112, the first bonding layer 112A and the second bonding layer 112B of the acoustic wave device 100 in the previous embodiments, which are not repeated herein. Referring to FIG. 12A, in the embodiment in which the sacrificial layer 210 and the support layer 211 are formed in the acoustic wave device 200, the first bonding layer 112A may be formed on the support layer 211 first, and then the bonding process 113 is used to bond the support layer 211 and the support substrate 114. As shown in FIG. 12A, the support layer 211 and the support substrate 114 are bonded to each other through the first bonding layer 112A. The first bonding layer 112A is the bonding layer 112. Referring to FIG. 12B, after the bonding step, the bonding interface 115 is present between the support substrate 114 and the bonding layer 112.

Similar to the acoustic wave device 100 of the above embodiments, the first electrode 108 may be bonded to the support substrate 114 through the manufacturing method provided by the embodiment of the application, and the bonding interface 115 is formed between the first electrode 108 and the support substrate 114. In some embodiments, the materials of the first bonding layer 112A and the support substrate 114 are metallic materials, and thus the bonding interface 115 is formed with metallic bonding. In some embodiments, the materials of the first bonding layer 112A and the support substrate 114 are non-metallic materials, and thus the bonding interface 115 is formed with non-metallic bonding, such as a covalently bonded interface or an adhesive bonding interface.

Referring to FIG. 12C, in other embodiments in which the sacrificial layer 210 and the support layer 211 are formed in the acoustic device 200, the first bonding layer 112A may also be formed on the support substrate 114 first, and then the bonding process 113 is used to bond the support layer 211 and the support substrate 114. As shown in FIG. 12C, the support layer 211 and the support substrate 114 are bonded to each other through the first bonding layer 112A. The first bonding layer 112A is the bonding layer 112. After the bonding step, the bonding interface is present between the support layer 211 and the bonding layer 112.

Referring to FIG. 12D, in other embodiments in which the sacrificial layer 210 and the support layer 211 are formed in the acoustic device 200, in addition to forming the first bonding layer 112A on the support layer 211, the second bonding layer 112B may be formed on the support substrate 114. Next, the support layer 211 and the support substrate 114 are bonded to each other by the bonding process 113 and through the first bonding layer 112A and the second bonding layer 112B. As a result, the bonding interface is present between the first bonding layer 112A and the second bonding layer 112B. However, the application is not limited thereto. In other embodiments, the first bonding layer 112A may be formed on the support substrate 114 first, and then the second bonding layer 112B may be formed on the support layer 211. Next, the support substrate 114 and the support layer 211 are bonded to each other by the bonding process 113. The material used for the second bonding layer 112B may be the same or similar to that of the first bonding layer 112A. In other embodiments, a different bonding material may also be used for the second bonding layer 112B from that of the first bonding layer 112A. In FIG. 12D, after completing the bonding step, the first bonding layer 112A and the second bonding layer 112B may collectively form the bonding layer 112, and thus the bonding interface is located within the bonding layer 112. In some embodiments, the materials of the first bonding layer 112A and the second bonding layer 112B are metallic materials, thereby forming the bonding interface with metallic bonding. In some embodiments, the materials of the first bonding layer 112A and the second bonding layer 112B are non-metallic materials, thereby forming the bonding interface with non-metallic bonding, such as a covalently bonded interface or an adhesive bonding interface.

Referring to FIG. 12E, in some embodiments, the support layer 211 and the support substrate 114 may be directly bonded to each other by the bonding process 113 without forming an additional bonding layer. After the bonding step, the bonding interface is present between the support layer 211 and the support substrate 114. In some embodiments, the support layer 211 is a non-metallic material, thereby forming the bonding interface with non-metallic bonding, such as a covalently bonded interface or an adhesive bonding interface.

Referring to FIG. 12F, according to other embodiments of the application, a support material layer 211A may be formed on the first electrode 108, and another support material layer 211B may be formed on the support substrate 114. Next, the bonding process 113 is used to bond the first electrode 108 and the support substrate 114, and the first electrode 108 and the support substrate 114 are bonded to each other through the support material layers 211A and 211B. After the bonding step, the support material layers 211A and 211B may collectively form the support layer 211, and the bonding interface is located within the support layer 211. In some embodiments, the support material layers 211A and 211B are non-metallic materials, thereby forming the bonding interface with non-metallic bonding, such as a covalently bonded interface or an adhesive bonding interface.

Using the embodiment shown in FIG. 12F for the bonding process, since the support layer 211 may be split into two parts (the support material layers 211A and 211B) for the bonding process, no additional bonding layer is required, and the bonding process may be performed in a lower temperature atmosphere as well to prevent the acoustic wave device 200 from severe warpage after the bonding process 113.

FIGS. 13-15 illustrate cross-sectional views of the subsequent processes of removing the growth substrate 102 and the decomposition layer 104 after bonding the first electrode 108 and the support substrate 114, and forming the second electrode 118 and removing the sacrificial layer 210 according to some embodiments of the application. Referring to FIG. 13, the growth substrate 102 and the decomposition layer 104 are removed to expose the piezoelectric layer 106. Similar to the aforementioned embodiments for the acoustic wave device 100, the laser lift-off process 116 may be used to remove the growth substrate 102 and the decomposition layer 104.

Next, referring to FIG. 14, the second electrode 118 is formed on the second surface 106S2 of the piezoelectric layer 106. The second surface 106S2 is opposite the first surface 106S1.

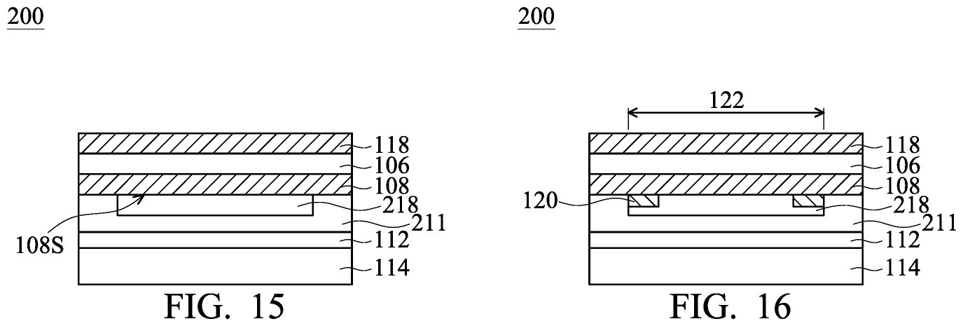

Next, referring to FIG. 15, after the formation of the second electrode 118, suitable selective etching processes may be used to remove the sacrificial layer 210 and to produce a cavity 218 between the support layer 211 and the first electrode 108. The etching process may include dry etching, wet etching, and/or other suitable processes. For example, the dry etching process may include plasma etching, reactive ion etching, inductively coupled plasma reactive ion etching, and the like, and may be performed by using plasma, gas, or a combination thereof. The gas may include oxygen-containing gas, fluorine-containing gas (such as hydrogen fluoride, carbon tetrafluoride, sulfur hexafluoride, difluoromethane, fluoroform, and/or hexafluoroethane), chlorine-containing gas (such as chlorine, chloroform, carbon tetrachloride, and/or boron trichloride), bromine-containing gases (such as hydrogen bromide and/or bromoform), iodine-containing gas, and/or combinations thereof. For example, the wet etching process may be performed by using acidic or alkaline solutions, or other suitable wet etching chemicals. The acidic solution may include hydrofluoric acid, phosphoric acid, hydrochloric acid, nitric acid, acetic acid, or combinations thereof. The alkaline solution may include a solution containing potassium hydroxide, ammonia, hydrogen peroxide, or a combination thereof. After the removal of the sacrificial layer 210, as shown in FIG. 15, a lower surface 108S of the first electrode 108 is exposed to the cavity 218.

Referring again to FIG. 15, according to the embodiments of the application, the resulting acoustic wave device 200 may include the support substrate 114, the first electrode 108 above the support substrate 114, the piezoelectric layer 106 on the first electrode 108, and the second electrode 118 on the piezoelectric layer 106. The bonding interface is present between the support substrate 114 and the first electrode 108. The bonding interface may be located between the support substrate 114 and the bonding layer 112 (the bonding interface 115 shown in the embodiments of FIG. 12B), between the bonding layer 112 and the support layer 211 (the embodiments shown in FIG. 12C), within the bonding layer 112 (the embodiments shown in FIG. 12D), between the support layer 211 and the support substrate 114 (the embodiments shown in FIG. 12E), or within the support layer 211 (the embodiments shown in FIG. 12F). In addition, the piezoelectric layer 106 may have a full width at half maximum of between about 10 arc-sec and about 1000 arc-sec in the X-ray diffraction pattern of the crystal plane <002>. Accordingly, in accordance with the embodiments provided in FIGS. 10, 11, 12A-12F, and 13-15, the piezoelectric layer 106 that is formed with the decomposition layer 104 may have better crystal quality and surface flatness, and thus the piezoelectric layer 106 may have better electromechanical coupling efficiency, and overall structural stability of the acoustic wave device 200 may be increased. On the other hand, the non-metallic bonding process with the aforementioned bonding materials may prevent the acoustic wave device 200 from warpage resulted from high temperature, and may result in a flatter bonding interface with non-metallic bonding. Therefore, structural stability of the acoustic wave device 200 may further be increased.

Next, referring to FIG. 16, FIG. 16 is a cross-sectional view of the acoustic wave device 200 according to other embodiments of the application. In the embodiments shown in FIG. 16, the acoustic wave device 200 further includes the tuning layer 120 between the support substrate 114 and the first electrode 108. The tuning layer 120 is in direct contact with a portion of the first electrode 108. Specifically, prior to the bonding step of first electrode 108 and the support substrate 114, the tuning layer 120 may be formed on a portion of the first electrode 108. In some specific embodiments, as shown in FIG. 16, the tuning layer 120 may be formed below a portion of the first electrode 108 that is located at the margin of the active region 122 of the acoustic wave device 200. Disposing the tuning layer 120 below a portion of the first electrode 108 that is located at the margin of the active region 122 of the acoustic wave device 200 may suppress the effect caused by the spurious mode during operation of the acoustic wave device 200, thereby reducing insertion loss of the acoustic wave device 200 and improving interference of the spurious mode in the bandwidth of the acoustic wave device 200.

The bonding process is performed with non-metallic materials (e.g., insulating materials, metal oxide materials, or semiconductor materials) and in a low temperature atmosphere for the acoustic wave device provided by the embodiments of the application to form covalent bonding. In this way, the bonding interface formed by the bonding process with covalent bonding may be flatter and may increase adhesion during bonding of the acoustic wave device. Furthermore, such bonding process may also prevent two parts of the acoustic wave device from severe warpage resulted from the difference in coefficients of thermal expansion after being bonded to each other. Therefore, the possibility of damage for the acoustic wave device caused by severe warpage may be reduced.

Table 1 shows wafer warpage of the acoustic wave device 100 using the bonding process of the embodiments shown in FIG. 8. In Table 1, the embodiment and the comparative embodiment respectively use silicon dioxide and gold (Au) with the same thickness as the bonding materials for the bonding process. In addition, the bonding process for the embodiment is performed at a temperature of about 200-300° C., and the bonding process for the comparative embodiment is performed at a temperature of about 400-500° C. Wafer warpage of the acoustic wave device may be evaluated by measuring one of the following three indices, including total thickness variation (TTV), warp, or bow. The TTV is the difference between the maximal thickness and the minimal thickness of the wafer, and is measured according to ASTM F657 standard testing method. The warp is the distance between the median surface and the reference plane of the wafer, and is measured according to ASTM F1390 standard testing method. The bow is a variation value of the center of the median surface with respect to the reference surface, and is measured according to ASTM F534 3.1.2 standard testing method.

TABLE 1
Wafer warpage of the acoustic wave device

| | TTV (μm) | Warp (μm) | Bow (μm) |
|---|---|---|---|
| Embodiment | 5-10 | 10-25 | 5-20 |
| Comparative | 70-110 | 80-120 | 60-80 |
| embodiment | | | |

As shown in Table 1, since the embodiment is a bonding process using silicon dioxide for covalent bonding in a low temperature atmosphere, the formed acoustic wave device exhibits less warpage in terms of TTV, warp, or bow. In general, non-metallic bonding processes, such as covalent bonding or adhesive bonding, can be performed at a temperature of between about 100° C. and about 300° C., and wafer warpage (including TTV, warp, and bow) may be controlled to a level of less than about 50 μm. However, the bonding process using metal as the bonding material is generally performed at a temperature of about 200° C. to about 500° C., and the wafer warpage (including TTV, warp, and bow) may be greater than about 70 μm. This indicates that using the process of the embodiment of application can avoid severe warpage of the two parts of the acoustic wave device caused by the difference in the coefficients of thermal expansion after the two parts are bonded to each other, thereby reducing the possibility of damage to the wafer forming the acoustic wave device.

On the other hand, a material with high resistance may be used for the non-metallic bonding process to reduce signal loss of the acoustic wave device and to increase the difference between the parallel resonance frequency (fp) and the series resonance frequency (fs), thereby increasing the electromechanical coupling efficiency (kt²). Therefore, the difference between the series and parallel resonance frequencies of the acoustic wave device 100 in FIG. 8 of the embodiment of the application is bigger, suggesting that it has a higher coefficient of electromechanical coupling, and that its conversion efficiency between electrical energy and acoustic energy (i.e., the electromechanical coupling efficiency) is superior to that of the acoustic wave devices with metallic materials for bonding.

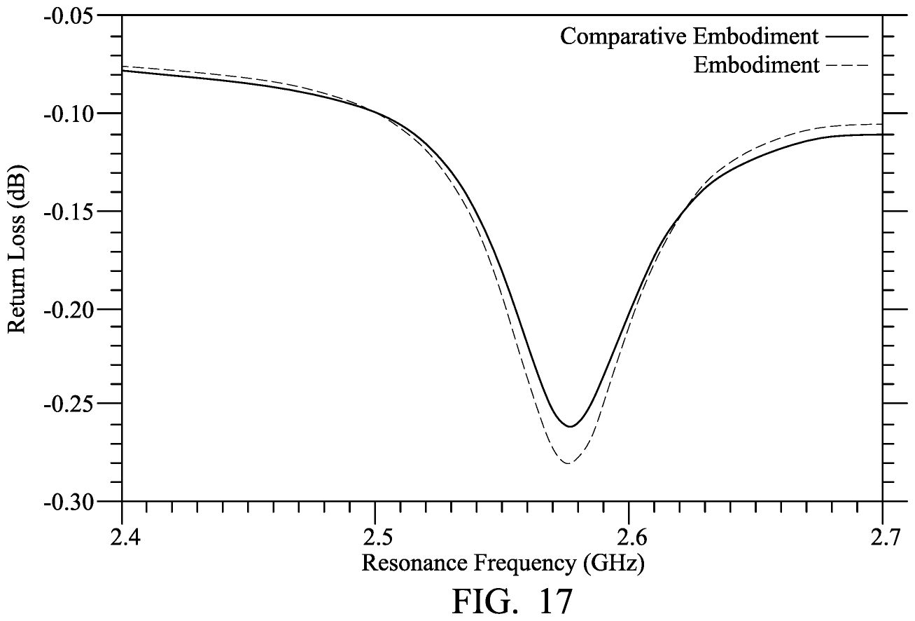

In addition, referring to FIG. 17, FIG. 17 is a frequency response pattern of a return loss test using the acoustic wave device 100 shown in FIG. 8 of the embodiments of the application. The conditions adopted for the embodiment and the comparative embodiment in FIG. 17 are the same as that in Table 1. As shown in FIG. 17, the acoustic wave device of the embodiment of the application has a larger return loss (i.e., a larger absolute value) in the main frequency band (e.g., about 2.5 GHz to about 2.6 GHz), suggesting that the echo wave generated from the acoustic wave device is weaker and may not affect the signal at the transmission end of the acoustic wave device. Therefore, the performance of the acoustic wave device may be enhanced by adopting the manufacturing method of the embodiments of the application.

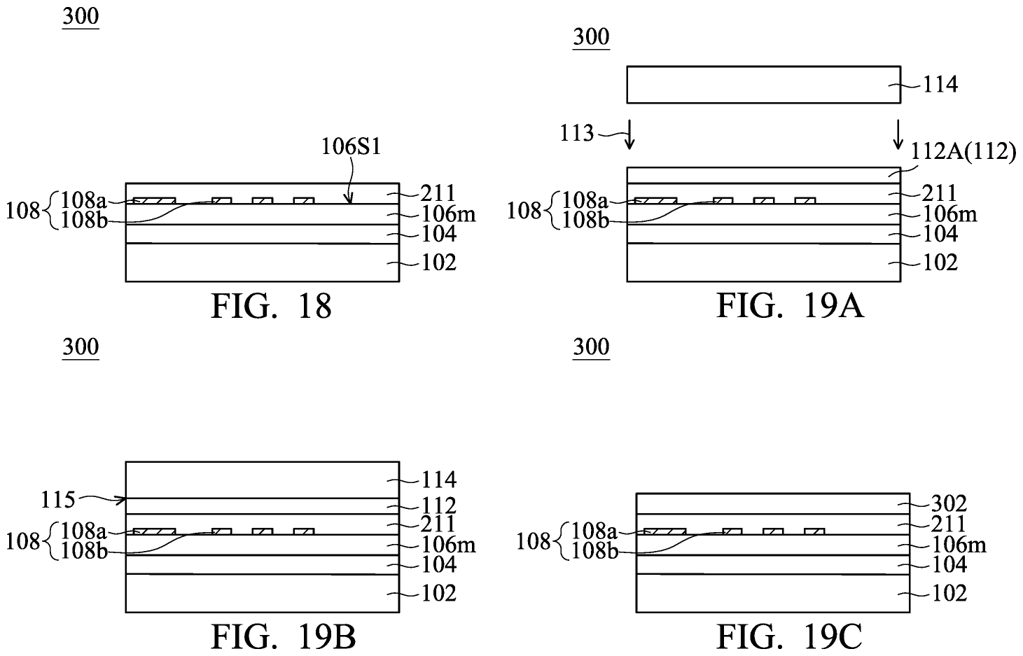

FIGS. 18, 19A-19E, and 20-22 illustrates cross-sectional views of an acoustic wave device 300 having interdigital electrodes at various intermediate stages of its manufacturing process according to other embodiments of the application. First, referring to FIG. 18, the acoustic wave device 300 shown in FIG. 18 is similar to the acoustic wave device 200 shown in FIG. 11, except that the first electrode 108 is disposed as a pair of interdigital positive and negative electrodes on the first surface 106S1 of a piezoelectric material layer 106m in the acoustic wave device 300. The first electrode 108 includes one or multiple first sub-electrodes 108a with a first conductivity-type and one or multiple first sub-electrodes 108b with a second conductivity-type. In addition, no sacrificial layer is disposed on the first surface 106S1 of the piezoelectric material layer 106m in the acoustic wave device 300. In particular, as shown in FIG. 18, in a direction parallels the main surface of the growth substrate 102, the first sub-electrodes 108a with the first conductivity-type and the first sub-electrodes 108b with the second conductivity-type are laterally and alternately disposed to form an electrode structure in an interdigital arrangement. In some embodiments, the first sub-electrodes 108a with the first conductivity-type may be positive electrodes, and the first sub-electrodes 108b with the second conductivity-type may be negative electrodes. In some embodiments, the first sub-electrodes 108a with the first conductivity-type may be negative electrodes, and the first sub-electrodes 108b with the second conductivity-type may be positive electrodes. In some embodiments, the pitch between the first sub-electrodes 108a with the first conductivity-type and the first sub-electrodes 108b with the second conductivity-type may be between about 200 nm and about 500 nm, such as about 300 nm. The acoustic wave device 300 with the electrodes whose pitch is in the aforementioned range may generate acoustic waves with higher frequency to adapt to high frequency communication devices, such as high frequency communication devices that can receive and/or transmit millimeter waves (e.g., acoustic waves with a frequency between about 18 GHz and about 27 GHz).

In addition, the support layer 211 is formed on the first surface 106S1 of the piezoelectric material layer 106m. In particular, as shown in FIG. 18, the support layer 211 may cover the first electrode 108 and fill the space between the first electrode 108. In these embodiments, a portion of the support layer 211 in the acoustic wave device 300 may be etched in the subsequent processes to form a cavity of the acoustic wave device 300 for acoustic wave reflection. In some embodiments, the support layer 211 may be first deposited on the first surface 106S1 of the piezoelectric material layer 106m to a level higher than the top surface of the first electrode 108. Next, a planarization process, such as chemical mechanical planarization, is performed to the support layer 211 and the first electrode 108 such that the top surface of the support layer 211 and the top surface of the first electrode 108 may be substantially coplanar. After the planarization process, the material of the support layer 211 may be further deposited until the volume is enough to accommodate the cavity formed in the following processes. In other embodiments, the material of the support layer 211 may be also deposited with a desired thickness directly, and then the planarization process, such as chemical mechanical planarization, is performed to the support layer 211 such that the support layer 211 can have a flat top surface, and the remaining volume of the support layer 211 is enough to accommodate the cavity formed in the following processes. According to some embodiments, the support layer 211 of the acoustic wave device 300 may have a thickness between about 2 μm and about 10 μm, such as about 3 μm. The material and the method for forming the support layer 211 may be similar to or the same as those described above, which are not repeated herein.

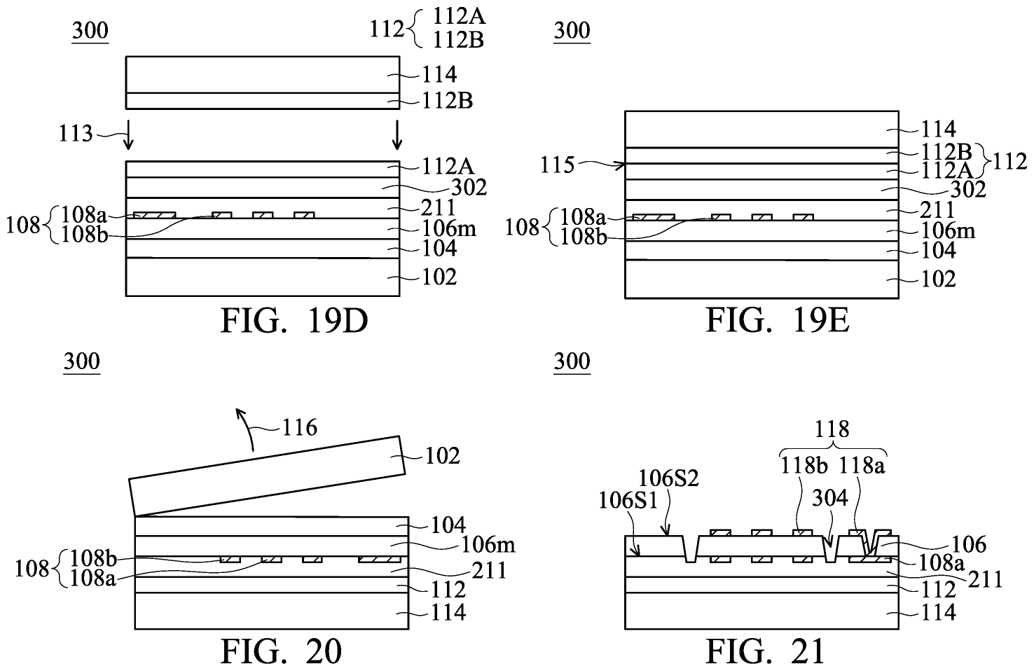

Next, referring to FIGS. 19A and 19B, the support substrate 114 is provided, and the support layer 211 and the support substrate 114 are bonded to each other. In some embodiments, as shown in FIGS. 19A and 19B, the first bonding layer 112A may be formed on the support layer 211, and the bonding process 113 is performed to bond the support layer 211 and the support substrate 114 through the first bonding layer 112A. After the bonding process 113, the first bonding layer 112A in the acoustic wave device 300 may be also referred to as “the bonding layer 112”. Furthermore, after the bonding process 113, the bonding interface 115 is present between the support layer 211 and the support substrate 114. In particular, in the embodiments shown in FIG. 19B, the bonding interface 115 may be between the bonding layer 112 and the support substrate 114. The material used for the first bonding layer 112 and the method suitable for the bonding process 113 are similar to or the same as those describe above, which are not repeated herein.

Although the first bonding layer 112A is illustrated to be formed on the support layer 211 in FIGS. 19A and 19B, but the application is not limited thereto. As described in the above embodiments, in other embodiments, the first bonding layer 112A may be formed on the support substrate 114 first, and the bonding process 113 is performed to bond the support layer 211 and the support substrate 114. In this way, the bonding interface 115 may be between the support layer 211 and the bonding layer 112A. Additionally, in some further embodiments, the support layer 211 and the support substrate 114 may be directly bonded to each other without formation of an additional bonding layer. Moreover, in some further embodiments, the first bonding layer 112A and the second bonding layer (such as the second bonding layer 112B in FIG. 12D) may be respectively formed on the support layer 211 and the support substrate 114, and then the bonding process 113 is performed to bond the support layer 211 and the support substrate 114. After the bonding process 113, the first bonding layer 112A and the second bonding layer may be collectively referred to as “bonding layer 112”. Accordingly, the bonding interface 115 may be between the first bonding layer 112A and the second bonding layer, namely in the bonding layer 112.

Referring to FIGS. 19C-19E, in some embodiments, an insulating layer 302 may be formed on the support layer 211, and the first bonding layer 112A and the second bonding layer 112B are respectively formed on the insulating layer 302 and the support substrate 114. Subsequently, the bonding process 113 is performed to bond the insulating layer 302 and the support substrate 114 through the first bonding layer 112A and the second bonding layer 112B. As shown in FIG. 19E, after the bonding of the insulating layer 302 and the support substrate 114 through the first bonding layer 112A and the second bonding layer 112B, the bonding interface 115 may be present between the first bonding layer 112A and the second bonding layer 112B. In addition, after bonding, the first bonding layer 112A and the second bonding layer 112B may be collectively referred to as “bonding layer 112”. Therefore, the bonding interface 115 may be in the bonding layer 112.

In some embodiments, the insulating layer 302 may include an insulating material with a high resistance property, such as silicon or any aforementioned dielectric materials. In some embodiments, the first bonding layer 112A and the second bonding layer 112B may include a metal material or a metal alloy material, such as gold, tin, indium, lead, germanium, or alloys thereof. In the embodiments in which the first bonding layer 112A and the second bonding layer 112B include a metal material or a metal alloy material, the insulating layer 302 may prevent electrical signal loss during the operation of the piezoelectric material layer 106 of the acoustic wave device 300, thereby increasing the signal intensity of the acoustic wave device 300 and/or maintaining the performance of the acoustic wave device 300.

Referring to FIG. 20, the growth substrate 102 and the decomposition layer 104 are removed to expose the piezoelectric material layer 106m. Specifically, in some embodiments, the growth substrate 102 and the decomposition layer 104 may be removed by the laser lift-off process 116, and the remaining decomposition layer 104 on the piezoelectric material layer 106m may be further removed by a suitable etching process. For example, the suitable etching process may include any aforementioned dry etching, wet etching, and/or other suitable etching processes. According to some embodiments, the etching process used to remove the remaining decomposition layer 104 may further remove a portion of the piezoelectric material layer 106m. As such, a portion of the piezoelectric material layer 106m that is initially formed with low crystal quality can be removed. Therefore, the acoustic wave device 300 may be manufactured to have the piezoelectric layer with better crystal quality, thereby increasing the performance of the acoustic wave device 300 (such as with a higher Q factor and/or higher electromechanical coupling efficiency).

Referring FIG. 21, a portion of the piezoelectric material layer 106m is etched to form the piezoelectric layer 106. The step of etching the piezoelectric material layer 106m includes forming multiple openings 304 in the piezoelectric material layer 106m. Part of the openings 304 may expose the support layer 211 and may be beneficial for the following processes to form the cavity of the acoustic wave device 300. Another part of the openings 304 may penetrate through the piezoelectric material layer 106m, and exposes one of the sub-electrodes of the first electrode 108 below the piezoelectric material layer 106m, such as one of the first sub-electrode 108a with the first conductivity-type. Next, the second electrode 118 is disposed as a pair of interdigital positive and negative electrodes on the second surface 106S2 of the piezoelectric layer 106 that is opposite to the first surface 106S1. The second electrode 118 includes one or multiple second sub-electrodes 118a with the first conductivity-type and one or multiple second sub-electrodes 118b with the second conductivity-type. The sub-electrodes of the second electrode 118 with the same conductivity-type as the first sub-electrodes 108a with the first conductivity-type, such as the second sub-electrodes 118a with the first conductivity-type, may be electrically connected to the first sub-electrodes 108a with the first conductivity-type through the aforementioned part of the openings 304. In particular, as shown in FIG. 21, in a direction parallel to the second surface 106S2 of the piezoelectric layer 106, the second sub-electrodes 118a with the first conductivity-type and the second sub-electrodes 118b with the second conductivity-type may be laterally and alternately disposed to form an electrode structure in an interdigital arrangement. In some embodiments, the second sub-electrodes 118a with the first conductivity-type may be positive electrodes, and the second sub-electrodes 118b with the second conductivity-type may be negative electrodes. In some embodiments, the second sub-electrodes 118a with the first conductivity-type may be negative electrodes, and the second sub-electrodes 118b with the second conductivity-type may be positive electrodes. In some embodiments, the first sub-electrodes 108a with the first conductivity-type and the second sub-electrodes 118a with the first conductivity-type are electrodes with the same conductivity-type, and the first sub-electrodes 108b with the second conductivity-type and the second sub-electrodes 118b with the second conductivity-type are electrodes with the same conductivity-type. In some embodiments, as shown in FIG. 21, in a direction perpendicular to the piezoelectric layer 106, the first sub-electrodes 108a with the first conductivity-type and the second sub-electrode 118a with the first conductivity-type, which have the same conductivity-type, are arranged correspondingly to each other, but the application is not limited thereto. In some other embodiments, in the direction perpendicular to the piezoelectric layer 106, the first sub-electrodes 108a with the first conductivity-type and the second sub-electrodes 118b with the second conductivity-type, which have different conductivity-types, are arranged correspondingly to each other. In some embodiments, as shown in FIG. 21, in addition to the formation of the second electrode 118 on the second surface 106S2 of the piezoelectric layer 106, one of the second sub-electrodes 118a with the first conductivity-type may further extend into and fill the opening 304 that is used as an electrical connection via to contact the one of the first sub-electrodes 108a with the first conductivity-type. In some embodiments, in addition to the formation of the second electrode 118 on the second surface 106S2 of the piezoelectric layer 106, one of the second sub-electrodes 118b with the second conductivity-type may further extend into and fill other opening (not shown) in the piezoelectric layer 106 that exposes one of the first sub-electrodes 108b with the second conductivity-type to contact the one of the first sub-electrodes 108b with the second conductivity-type. During the operation of the acoustic wave device 300, the electrical connection of the sub-electrodes with the same conductivity-type between the first electrode 108 and the second electrode 118 may combine the input or output voltage signal to apply to the sub-electrodes of the first and second electrodes 108 and 118 with the same conductivity-type.

In some embodiments, the piezoelectric layer 106 of the acoustic wave device 300 may be formed by metal organic chemical vapor deposition (MOCVD), molecular beam epitaxy (MBE), liquid phase epitaxy (LPE), vapor phase epitaxy (VPE), or combinations thereof. In some embodiments, the piezoelectric layer 106 may be a monocrystalline layer. In other embodiments, the piezoelectric layer 106 may be a polycrystalline layer. In some embodiments, the piezoelectric layer 106 may be a combination of the monocrystalline layer and the polycrystalline layer. For example, the piezoelectric layer 106 may be initially formed as the polycrystalline layer and may gradually become the monocrystalline layer along the growth direction. In some embodiments, the piezoelectric material of the piezoelectric layer 106 may include monocrystalline AlN, polycrystalline AlN, monocrystalline ScAlN, polycrystalline ScAlN, or combinations thereof. In some embodiments, the piezoelectric layer 106 of the acoustic wave device 300 may have a thickness between about 50 nm and about 500 nm. In some embodiments, the full width at half maximum of the piezoelectric layer 106 in the X-ray diffraction pattern of the crystal plane <002> may be between about 10 arc-sec and about 3600 arc-sec. In one embodiment, the full width at half maximum of the piezoelectric layer 106 in the X-ray diffraction pattern of the crystal plane <002> may be between about 10 arc-sec and about 2520 arc-sec. In one embodiment, the full width at half maximum of the piezoelectric layer 106 in the X-ray diffraction pattern of the crystal plane <002> may be between about 10 arc-sec and about 360 arc-sec. Since the piezoelectric layer 106 has the thickness and the full width at half maximum in the X-ray diffraction pattern of the crystal plane <002> within the aforementioned range, the acoustic wave device 300 may have the better electromechanical coupling efficiency to efficiently convert electrical energy into mechanical energy or convert mechanical energy into electrical energy. Therefore, such an acoustic wave device may be useful in high frequency communication devices that transmit millimeter waves.

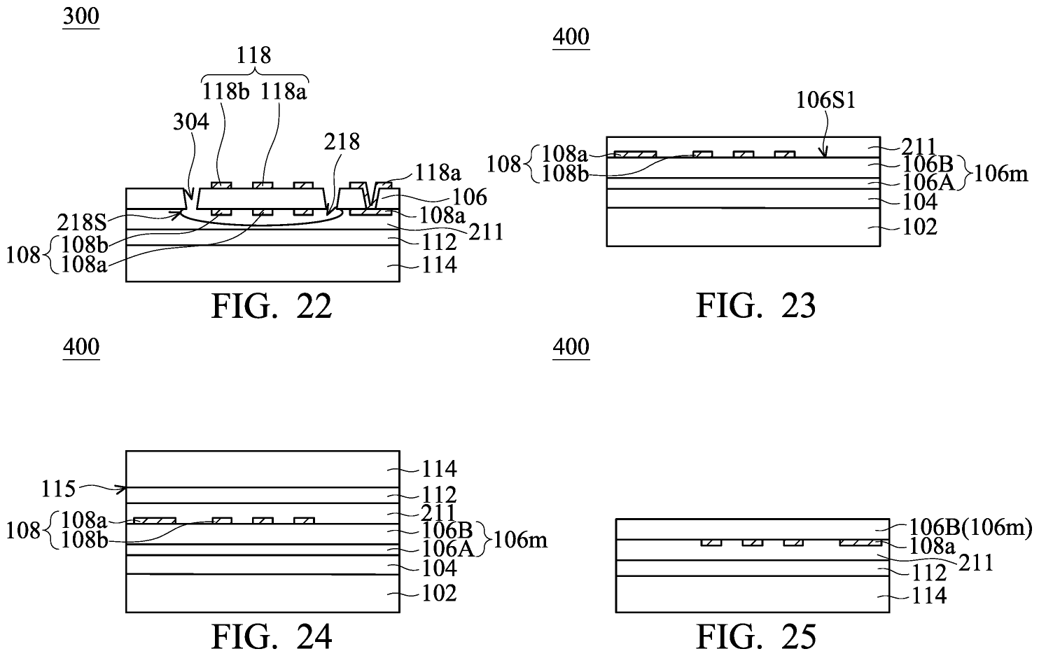

Referring to FIG. 22, a portion of the support layer 211 is removed to form the cavity 218 between the piezoelectric layer 106 and the bonding layer 112. Specifically, suitable etchants may be selected according to the material of the support layer 211 to remove a portion of the support layer 211 through the openings 304 to form the cavity 218. Suitable etching processes may include isotropic etching process. For instance, when the material of the support layer 211 includes silicon, a vapor etching process using XeF₂ as the etchant may be adopted. In some embodiments, as shown in FIG. 22, the cavity 218 may have an arc profile with a continuous curvature. In some embodiments, the sidewall 218S of the cavity 218 may have an undercut profile or a concave profile because of over-etching of the etchant to the support layer 211. Specifically, the above arc profile and concave profile may be a curve bending toward a direction away from the cavity. In addition, in accordance with some embodiments, after the formation of the cavity 218, the first electrode 108 may be exposed in the cavity 218.

During the operation of the acoustic wave device 300 shown in FIG. 22, receiving or inputting electrical signals by the acoustic wave device 300 through the electrodes may enable the piezoelectric layer 106 to vibrate and generate acoustic wave resonance in the horizontal and vertical directions. Alternatively, acoustic wave resonance may induce the vibration of the piezoelectric layer 106 in the horizontal and vertical directions, thereby outputting electrical signals through the electrodes. Since total reflection can occur at the interface between the piezoelectric layer 106 and the cavity 218, the cavity 218 may reduce energy loss of the acoustic wave during transmission, namely reducing acoustic wave loss of the piezoelectric layer 106, thereby reducing insertion loss of the acoustic wave device 300. Accordingly, when the cavity 218 is designed to have an arc profile, the acoustic wave transmitted in the horizontal and vertical directions is more likely to be reflected toward the piezoelectric layer 106 to ensure that the acoustic wave device 300 can convert electrical signals and acoustic wave signals more efficiently.

FIGS. 23-26 illustrate cross-sectional view of an acoustic wave device 400 having the piezoelectric material layer 106m formed by different methods according to some further embodiments of the application. The acoustic wave device 400 of FIG. 23 is similar to the acoustic wave device 300 of FIG. 18, except that the piezoelectric material layer 106m of the acoustic wave device 400 further includes a first piezoelectric material layer 106A and a second piezoelectric material layer 106B. In particular, in some embodiments, the first piezoelectric material layer 106A may be epitaxially grown on the decomposition layer 104 by a suitable epitaxial process, and the second piezoelectric material layer 106B may be deposited on the first piezoelectric material layer 106A by a suitable deposition process. In the embodiments shown in FIG. 23, the first piezoelectric material layer 106A may be used as a seed layer during the deposition of the second piezoelectric material layer 106B so that the second piezoelectric material layer 106B may have better crystal quality. For example, the first piezoelectric material layer 106A may be formed by suitable epitaxial processes, such as metal organic chemical vapor deposition (MOCVD), molecular beam epitaxy (MBE), liquid phase epitaxy (LPE), vapor phase epitaxy (VPE), or combinations thereof. For example, the second piezoelectric material layer 106B may be formed by suitable physical vapor deposition processes, such as sputtering, evaporation, ion plating, or combinations thereof. However, in other embodiments, the second piezoelectric material layer 106B may be also epitaxially grown by the aforementioned suitable epitaxial processes to enhance crystal quality of the second piezoelectric material layer 106B.

The first piezoelectric material layer 106A and the second piezoelectric material layer 106B may include any aforementioned piezoelectric materials. In some embodiments, the first piezoelectric material layer 106A and the second piezoelectric material layer 106B may include monocrystalline AN, polycrystalline AN, monocrystalline ScAlN, polycrystalline ScAlN, or combinations thereof. In some embodiments, the first piezoelectric material layer 106A includes AN. In some embodiments, the first piezoelectric material layer 106A includes a monocrystalline piezoelectric material to enable the second piezoelectric material layer 106B subsequently formed thereon to have better crystal quality. In some specific embodiments, the first piezoelectric material layer 106A includes monocrystalline AlN. In some embodiments, the second piezoelectric material layer 106B includes ScAlN. In some embodiments, the second piezoelectric material layer 106B includes a monocrystalline piezoelectric material, a polycrystalline piezoelectric material, or a combination thereof. In some specific embodiments, the second piezoelectric material layer 106B includes monocrystalline ScAlN or AlN, polycrystalline ScAlN or AlN, or a combination thereof. According to some embodiments, the thickness of the first piezoelectric material layer 106A may be between about 100 nm and about 200 nm, such as about 150 nm. According to some embodiments, the thickness of the second piezoelectric material layer 106B may be between about 50 nm and about 500 nm.

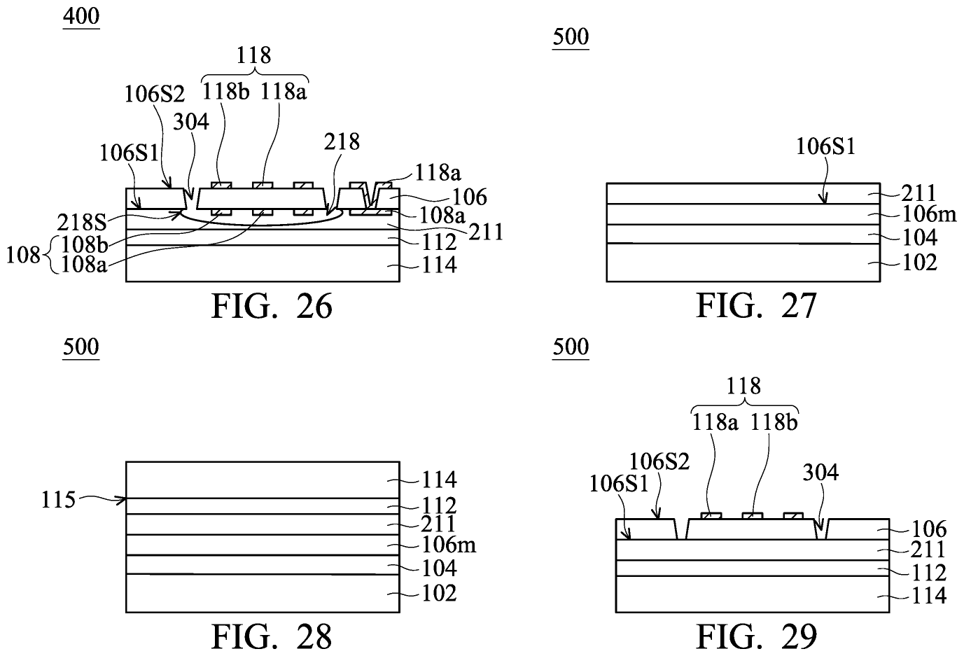

Next, referring to FIGS. 24 and 25, the support layer 211 and the support substrate 114 may be bonded to each other by using the bonding steps discussed with reference to FIGS. 19A-19E, and the growth substrate 102 and the decomposition layer 104 may be removed by using the removing steps discussed with reference to FIG. 20. Afterwards, a portion of the piezoelectric material layer 106m is etched to form the piezoelectric layer 106. In detail, referring to FIGS. 25 and 26, in some embodiments, the step of etching a portion of the piezoelectric material layer 106m includes removing the first piezoelectric material layer 106A by suitable etching methods to expose the second piezoelectric material layer 106B. In some embodiments, the step of removing the first piezoelectric material layer 106A can only remove a portion of the first piezoelectric material layer 106A. The remaining first piezoelectric material layer 106A and the second piezoelectric material layer 106B may be the piezoelectric material layer 106m accordingly. In some embodiments, the step of removing the first piezoelectric material layer 106A can completely remove the first piezoelectric material layer 106A and can further remove a portion of the second piezoelectric material layer 106B to expose the second piezoelectric material layer 106B. The remaining second piezoelectric material layer 106B may be the piezoelectric material layer 106m accordingly. In some embodiments, the step of etching a portion of the piezoelectric material layer 106m further includes etching the piezoelectric material layer 106m to form the openings 304 and to form the piezoelectric layer 106 after removing the first piezoelectric material layer 106A. Part of the openings 340 may expose one of the first sub-electrodes 108a with the first conductivity-type below the piezoelectric layer 106. The above methods for removing the first piezoelectric material layer 106A and for etching the piezoelectric material layer 106m to form the openings 304 may adopt any aforementioned etching processes, which are not repeated herein. As described in the prior embodiments, after the formation of the piezoelectric layer 106, the second electrode 118 may be formed, and the support layer 211 may be etched through the openings 304 to form the cavity 218.

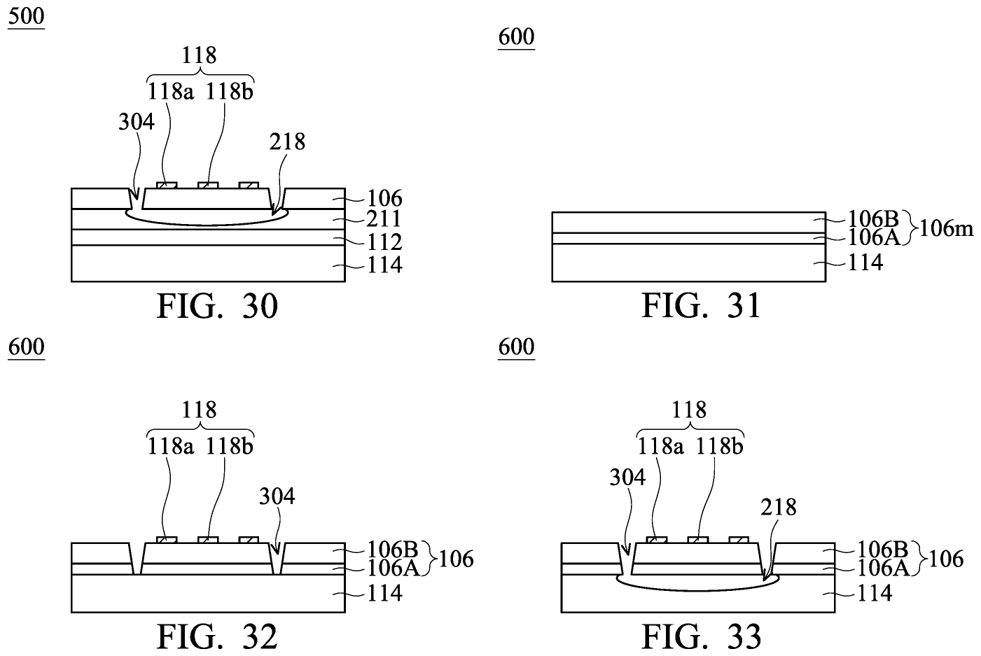

FIGS. 27-30 illustrate cross-sectional views of an acoustic wave device 500 only having the second electrode 118 at various intermediate stages of its manufacturing process according to other embodiments of the application. Referring to FIG. 27, the acoustic wave device 500 of FIG. 27 is similar to the acoustic wave device 300 of FIG. 18, except that no first electrode is disposed on the first surface 106S1 of the piezoelectric material layer 106m. Referring to FIGS. 28 and 29, the support layer 211 and the support substrate 114 may be bonded to each other by using the bonding steps discussed with reference to FIGS. 19A-19E, and the growth substrate 102 and the decomposition layer 104 may be removed by using the removing steps discussed with reference to FIG. 20. Subsequently, the second electrode 118 is formed on the second surface 106S2 of the piezoelectric material layer 106m, and a portion of the piezoelectric material layer 106m is removed to form the piezoelectric layer 106. In particular, a portion of the piezoelectric material layer 106m is etched to form the openings 304 that expose the support layer 211. Afterwards, referring to FIG. 30, a portion of the support layer 211 is etched through the openings 304 by suitable etching methods to form the cavity 218 between the bonding layer 112 and the piezoelectric layer 106.

FIGS. 31-33 illustrate cross-sectional views of an acoustic wave device 600 at various intermediate stages of its manufacturing process according to other embodiments of the application. The difference between the acoustic wave device 600 shown in FIGS. 31-33 and the acoustic wave devices discussed in the prior embodiments is that the acoustic wave device 600 is manufactured by using the support substrate as a growth substrate. Referring to FIG. 31, the piezoelectric material layer 106m is formed on the support substrate 114. Specifically, the first piezoelectric material layer 106A is epitaxially grown on the support substrate 114 by an epitaxial process. In some embodiments, as shown in FIG. 31, the first piezoelectric material layer 106A may be epitaxially grown as a seed layer, and then the second piezoelectric material layer 106B may be formed thereon by a suitable deposition process or epitaxial processes. In some embodiments, in FIG. 31, the first piezoelectric material layer 106A and the second piezoelectric material layer 106B may be collectively referred to as “the piezoelectric material layer 106m”. For example, the suitable processes may include any aforementioned epitaxial processes, physical vapor deposition processes, or combinations thereof. In other embodiments, the first piezoelectric material layer 106A may be epitaxially grown directly to have a desired thickness without additional formation of the second piezoelectric material layer 106B. Therefore, the first piezoelectric material layer 106A may become the piezoelectric material layer 106m after completing the following processes. In these embodiments, the thickness of the first piezoelectric material layer 106A may be between about 50 nm and about 500 nm. Furthermore, the first piezoelectric material layer 106A may include a monocrystalline piezoelectric material. In some embodiments, the thickness of the first piezoelectric material layer 106A as the seed layer may be, for example, between about 100-150 nm. In some embodiments, the thickness of the second piezoelectric material layer 106B may be between about 50 nm and about 500 nm. Furthermore, the first piezoelectric material layer 106A may include a monocrystalline piezoelectric material, and the second piezoelectric material layer 106B may include a monocrystalline or polycrystalline piezoelectric material. In some embodiments, the sum of the thickness of the first piezoelectric material layer 106A and the second piezoelectric material layer 106B may be in a range between about 50 nm and about 500 nm.

Next, referring FIGS. 32 and 33, a portion of the piezoelectric material layer 106m may be removed to form the piezoelectric layer 106. In particular, a portion of the first piezoelectric material layer 106A and a portion of the second piezoelectric material layer 106B are etched to form the openings 304 that expose the support substrate 114. The piezoelectric layer 106 is formed after etching the first piezoelectric material layer 106A and the second piezoelectric material layer 106B. Afterwards, a portion of the support substrate 114 may be etched through the openings 304 by a suitable etching method to form the cavity 218 between the support substrate 114 and the piezoelectric layer 106.

In summary, by disposing the decomposition layer with a superlattice structure prior to forming the piezoelectric layer, the subsequently formed piezoelectric layer may not only have better surface flatness but also have better crystal quality. The piezoelectric layer with better surface flatness and better crystal quality may enhance the overall structural stability and electromechanical coupling efficiency of the acoustic wave device. Moreover, in the process of forming the acoustic wave device, a non-metallic bonding process may be performed in a low temperature environment using non-metallic materials as bonding materials. In this way, severe warpage caused by the difference in the coefficients of thermal expansion of the two parts of the acoustic wave device can be avoided after bonding to each other. On the other hand, using non-metallic materials for bonding can also prevent the bonding materials from affecting the signal when the acoustic wave element operates, thereby improving the performance of the acoustic wave device. The acoustic wave device provided by the embodiments of the application may have high Q factor and high electromechanical coupling efficiency and may receive and transmit acoustic waves with high frequency, and is suitable for communication devices transmitting signals with high frequency or any electronic devices transmitting signals wirelessly.

The foregoing outlines features of several embodiments so that those skilled in the art may better understand the aspects of the present application. Those skilled in the art should appreciate that they may readily use the present application as a basis for designing or modifying other processes and structures for carrying out the same purposes and/or achieving the same advantages of the embodiments introduced herein. Those skilled in the art should also realize that such equivalent constructions do not depart from the spirit and scope of the present application, and that they may make various changes, substitutions, and alterations herein without departing from the spirit and scope of the present application.

What is claimed is:

1. A method for manufacturing an acoustic wave device, comprising:
providing a growth substrate;
forming a decomposition layer on the growth substrate, wherein the decomposition layer comprises a III-V compound semiconductor material;
epitaxially growing a piezoelectric layer on the decomposition layer, wherein the piezoelectric layer is formed of a piezoelectric material, and wherein an energy gap of the III-V compound semiconductor material is less than an energy gap of the piezoelectric material;
forming a first electrode on a first surface of the piezoelectric layer;
providing a support substrate;
bonding the first electrode and the support substrate, wherein a bonding interface is present between the first electrode and the support substrate;
removing the growth substrate; and
forming a second electrode on a second surface of the piezoelectric layer that is opposite the first surface.

2. The method of claim 1, wherein the piezoelectric material comprises AN or ScAlN.

3. The method of claim 1, wherein the decomposition layer comprises a superlattice structure.

4. The method of claim 3, wherein the superlattice structure comprises stacking alternating layers of a first semiconductor layer comprising AlₓGa₁₋ₓN and a second semiconductor layer comprising Al_{y}Ga_{1-y}N, wherein y is greater than x, and wherein each of x and y is between 0 and 1.0.

5. The method of claim 4, wherein an energy gap of the second semiconductor layer is between the energy gap of the piezoelectric material and an energy gap of the first semiconductor layer.

6. The method of claim 4, wherein the removing the growth substrate comprises irradiating the decomposition layer with a laser light whose energy gap is between an energy gap of the second semiconductor layer and an energy gap of the first semiconductor layer.

7. The method of claim 1, further comprising forming a first bonding layer on the first electrode or on the support substrate prior to the step of bonding the first electrode and the support substrate, wherein the step of bonding the first electrode and the support substrate comprises bonding the first electrode and the support substrate through the first bonding layer, and wherein the bonding interface is present between the support substrate and the first bonding layer or between the first electrode and the first bonding layer.

8. The method of claim 7, wherein a material of the first bonding layer comprises an insulating material, a semiconductor material, or a metal oxide material.

9. The method of claim 8, wherein the insulating material comprises silicon dioxide, benzocyclobutene (BCB), silicon nitride, wax, epoxy resin, UV curing glue, photoresist or a combination thereof, the semiconductor material comprises polycrystalline silicon (poly-Si), and the metal oxide material comprises aluminum oxide, indium tin oxide, or a combination thereof,

10. The method of claim 1, further comprising forming a buffer layer between the growth substrate and the decomposition layer.

11. An acoustic wave device, comprising:
a substrate;
a first electrode on the substrate, wherein a bonding interface is present between the first electrode and the substrate;
a piezoelectric layer on the first electrode, wherein a full width at half maximum (FWHM) in an X-ray diffraction pattern of a crystal plane <002> of the piezoelectric layer is between 10 arc-sec and 3600 arc-sec; and
a second electrode on the piezoelectric layer.

12. The acoustic wave device of claim 11, further comprising a bonding layer between the substrate and the first electrode, wherein the bonding layer comprises an insulating material, a semiconductor material, or a metal oxide material, and wherein the bonding interface is present between the substrate and the bonding layer.

13. The acoustic wave device of claim 12, wherein the insulating material comprises silicon dioxide, benzocyclobutene, silicon nitride, wax, epoxy resin, UV curing glue, photoresist or a combination thereof, the semiconductor material comprises polycrystalline silicon, and the metal oxide material comprises aluminum oxide, indium tin oxide, or a combination thereof,

14. The acoustic wave device of claim 12, further comprising an acoustic wave reflective structure disposed between the bonding layer and the first electrode, wherein the acoustic wave reflective structure comprises an acoustic wave reflective layer or a cavity.

15. The acoustic wave device of claim 14, wherein the acoustic wave reflective layer comprises a distributed Bragg reflector (DBR) structure.

16. The acoustic wave device of claim 11, wherein the bonding interface is a non-metallic bonding interface.

17. The acoustic wave device of claim 16, wherein the bonding interface is a covalently bonded interface or an adhesive interface.

18. The acoustic wave device of claim 11, wherein a thickness of the piezoelectric layer is between 0.05 μm and 10 μm.

19. The acoustic wave device of claim 11, wherein a lower surface of the piezoelectric layer contacting the first electrode and an upper surface of the piezoelectric layer contacting the second electrode, and wherein a roughness (Ra) of the upper surface and the lower surface is between 0.01 nm and 5 nm.

20. The acoustic wave device of claim 11, further comprising a tuning layer between the first electrode and the substrate, wherein the tuning layer is in direct contact with a portion of the first electrode.
